(19) United States
(12) Patent Application Publication
(10) Pub. No.: US 2010/0108124 A1
(43) Pub. Date: May 6, 2010

(54) SOLAR ENERGY CONCENTRATOR

(75) Inventors: Richard M. Knox, Lago Vista, TX (US); Chanda B. Walker, Houston, TX (US)

Correspondence Address: OBLON, SPIVAK, MCCLELLAND MAIER & NEUSTADT, L.L.P., 1940 DUKE STREET, ALEXANDRIA, VA, 22314, US

(73) Assignee: RayDyne Energy, Inc., Lago Vista, TX (US)

(21) Appl. No.: 12/572,913

(22) Filed: Oct. 2, 2009

Related U.S. Application Data
(60) Provisional application No. 61/102,306, filed on Oct. 2, 2008.

(51) Int. Cl. H01L 31/052; G02B 5/10; G02B 6/10

(52) U.S. Cl. 136/246; 359/853

(57) ABSTRACT

A solar concentrator assembly comprises a stepped wave-guide assembly, a reflective mirror assembly, and an optical target providing unit. The stepped wave-guide assembly includes at least one surface, comprising a set of parallel but offset adjacent surfaces, and an opposing surface. The wave-guide assembly propagates light in a total internal reflection mode between the at least one surface and the opposing surface. The wave-guide assembly also includes transition surfaces between the adjacent parallel surfaces and the transition surfaces include edges perpendicular to a longitudinal axis of the wave-guide assembly. The reflective mirror assembly includes a plurality of mirrors each being aligned to reflect the light to one of the transition surfaces between two of the parallel adjacent surfaces. The optical target providing unit converts solar energy from the light propagated in the wave-guide assembly to a different form of energy.

### CROSS-REFERENCE TO RELATED APPLICATION

The present application claims priority to U.S. Provisional Application No. 61/102,306, filed on Oct. 2, 2008, the entire contents of which are incorporated by reference herein.

### FIELD OF THE INVENTION

The present invention relates generally to solar panels used to generate electrical or thermal power. More specifically the present invention relates to concentrator solar panels utilizing photovoltaic cells to generate electrical power.

### BACKGROUND OF THE INVENTION

Concentrators for solar energy have been in use for many years. These devices are used to focus the sun's energy into a small area to raise the power level being concentrated on a photovoltaic converter to generate electrical power directly, or on a fluid line to heat water to make steam to drive a turbine to generate electrical power.

One difficulty with these concentrators has been that they are generally large and bulky and are not suitable for residential applications or other locations where the aesthetics of the installation are of importance. Additionally they are very susceptible to environmental damage due to wind and other elements.

In a common implementation a refractive or reflective lens is used to focus the energy on a small photovoltaic device. An example of a refractive device 100 is presented in FIG. 1 and shows a refractive lens 104 concentrating solar illumination 108 on a photovoltaic cell 112. This simple device concentrates light in a manner similar to the child's experiment wherein sunlight passing through a magnifying glass is focused onto a sheet of paper, thus setting it alight. Arrays of these are ganged together to generate greater amounts of power. An example of a reflective solar concentrator device 200 previously disclosed in FIG. 3 of U.S. Pat. No. 4,177,083, the contents whereof are incorporated by reference, is presented in FIG. 2. The optical principle is identical to that of a Cassegrain telescope first made known in the seventeenth century, with an energy conversion device replacing the eyepiece. Specifically, solar illumination 204 enters the device 200 and is reflected off of a main reflector 208 to a sub-reflector 212. The sub-reflector 212 reflects the illumination 204 to a photovoltaic cell 216. It suffers from the deficiency that the sub-reflector 212 blocks a substantial portion of the aperture of the main reflector 208 and thus decreases the ability of the device to concentrate light.

Stepped wave guides have long been known in the art. In U.S. Pat. No. 5,202,950, Arego et al, and U.S. Pat. No. 5,050,946, Hathaway et al, the contents of which are incorporated herein by reference in their entirety, one inventor of the present invention discloses a faceted light pipe and a light pipe system suitable to backlight a transmissive liquid crystal display from a single side light. In Arego et al, FIG. 8 depicts one embodiment of the light pipe further described in column 6, line 53, to column 7, line 58. FIG. 3 of this document repeats FIG. 8 previously referenced. In FIG. 3 the front surface portion 304 and the rear surface portion 308 of the light pipe 320 are substantially parallel. As stated in Arego et al these surfaces are specular surfaces so as to avoid diffuse reflections or refraction that make control of the light path more difficult. The light facet 312 is oriented at an angle α of 135° from the parallel rear surface portion 308. The light facets 312 are optionally coated with a reflective material 316, stated to be aluminum. The light facet 312 is designed to perform an angle transformation on light propagating in TIR mode within the light pipe 320 to allow that light to exit the light pipe 320 in order to provide illumination for the LCD.

Faceted light pipes like those disclosed by Arego et al. have also been described in solar applications in U.S. Pub. No. 2009/0064993 to Ghosh et al. (Banyan). However, there remains a need for an improved system that can yield higher efficiency and be practically manufactured at a reasonable cost.

The cost advantages of a solar concentrator can best be realized if the concentration ratio is high. Highly efficient photovoltaic converters (PVC) can efficiently convert a flux density equivalent to many hundreds of suns. Concentration ratios approaching 1000:1 and higher are considered desirable. The concentration goal is best determined after consideration of the technical and cost constraints a solar concentrator system must satisfy.

### SUMMARY OF THE INVENTION

A light concentrator in the form of a relatively thin, planar assembly takes sunlight in at an orientation normal to the planar surface and direct it via a plurality of small linear aspheric or spheric sections into a TIR (total internal reflection) light guide which collects and transports the sunlight from the linear aspheric sections to one edge of the light guide where it illuminates a solar photovoltaic converter or heats water or other medium. As is well known in the art of light guides, TIR is the most efficient method for transporting light within a wave-guide. The efficiency of reflection is nominally 100% with the only losses coming from the transmission efficiency of the optical material. Optionally the solar energy may undergo an additional stage of concentration, for example through the use of a Simple Parabolic Concentrator (SPC) or similar device.

The concentrator of the present invention can include a plurality of aspheric mirror sections in a first stage, or element of concentration in the system. (Refer to FIG. 4 and associated text for an explanation of the following terminology regarding orientation used in this application.) Each aspheric mirror section concentrates light by illuminating a turn mirror that redirects the light down a wave guide (light pipe) that relies upon Total Internal Reflection (TIR) and geometric optics to contain the light within the wave guide. In one embodiment the aspheric section concentrates light only in the longitudinal axis of these aspheric sections. Additional concentration, or gain, may be had to this axis and to the perpendicular axis thus providing two additional stages of gain.

A concentrator with very high gain and a method of constructing a concentrator using plastic extrusion and aluminum or silver metallization to produce low cost, thin concentrators with very high gain is described.

### BRIEF DESCRIPTION OF THE DRAWINGS

FIG. 1 depicts a known refractive solar concentrator.

FIG. 2 depicts a known reflective solar concentrator based on Cassegrain optics.

FIG. 3 is a depiction of a wave-guide from the backlight assembly of a flat panel liquid crystal display.

FIG. 4 presents an isometric view of an exemplary embodiment of a set of principle elements in a solar concentrator after the present invention.

FIG. 5 presents a side view of an exemplary embodiment of a wave-guide after the present invention.

FIG. 6A presents an isometric view of an exemplary embodiment of a mirror assembly after the present invention comprising a plurality of mirror sections.

FIG. 6B presents an isometric view of a trough mirror section.

FIG. 7 presents an isometric view of a Simple Parabolic Concentrator (SPC).

FIG. 8A is a depiction of a basic wave-guide based solar concentrator with turn mirrors on the wave-guide assembly and with a series of trough mirrors in fixed relationship thereto.

FIG. 8B provides a detail of a turn mirror and its positioning on a segment of the wave-guide.

FIG. 9A depicts the geometrical and optical relationship between the Wave-Guide Assembly and the Trough Mirror Assembly.

FIG. 9B depicts details of a section of the assembly further depicting a set of ray traces that illustrate how light from the Trough Mirror Assembly enters the Wave-Guide Assembly and is converted to Total Internal Reflection.

FIG. 10A depicts an alternative turn mirror arrangement wherein an air gap exists between an angled surface of a wave-guide assembly and the turn mirror.

FIG. 10B depicts a functioning of the alternative mirror arrangement wherein the mode of reflection from the angled surface is Total Internal Reflection.

FIG. 10C depicts a function of the alternative mirror arrangement wherein the mode of reflection is a first surface reflection from the mirror.

FIG. 10D depicts a means for attaching the mirror of FIG. 10B to the Wave-Guide Assembly.

FIG. 11A depicts an arrangement of the inventive assembly illustrating a shift in curvature.

FIG. 11B depicts Section 1 of the mirror assembly of FIG. 11A located adjacent to the SPC.

FIG. 11C depicts Section 2 of the mirror assembly of FIG. 11A located at the end opposite the SPC.

FIG. 12A depicts an arrangement of the SPC in relation to the Wave-Guide Assembly and the Trough Mirror Assembly.

FIG. 12B is a detailed depiction of the arrangement of FIG. 12A.

FIG. 12C depicts a difference in material of the SPC and the wave-guide.

FIG. 12D depicts one method of attaching the SPC to the Wave Guide Assembly.

FIG. 13A presents an overhead view illustrating a ray trace showing the movement of solar energy down the Wave-Guide and into the SPC.

FIG. 13B is a side view of a ray trace illustrating the TIR motion of solar energy through the wave guide.

FIG. 14 presents an annotated isometric view of a solar concentrator with key elements identified for reference in tables.

FIG. 15A presents an exploded isometric view of an array of solar concentrators and their photovoltaic cells.

FIG. 15B depicts the assembled solar energy concentrator assembly.

FIG. 15C depicts an exploded view of a weather housing for a solar energy concentrator assembly.

FIG. 15D depicts the assembled weatherproof solar energy concentrator.

FIG. 16 depicts an alternative solar energy concentrator unit in which the SPC is illuminated underneath by a trough minor.

FIG. 17 depicts the areas where the reflection from the trough minor is not captured.

FIG. 18 illustrates the location of turn minors relative to the trough mirrors.

FIG. 19A depicts a side view illustrating the location of turn mirrors and the change of materials.

FIG. 19B provides an isometric illustration of the positions of the materials.

FIG. 20 provides an isometric illustration of an alternative embodiment in which the mirror under the SPC is a compound mirror.

FIG. 21 presents an isometric view of a compound mirror segment.

FIG. 22 provides an isometric view of ray traces from the compound mirror into the SPC.

FIG. 23 provides an isometric view of an embodiment without an SPC in which all mirrors on the mirror assembly are compound mirrors.

FIG. 24 presents an isometric view of a section of a solar concentrator with exemplary ray traces.

FIG. 25 illustrates the focus of the collected light within the SPC onto the photovoltaic cell as viewed from above the device.

FIG. 26 provides an alternative in which the SPC is present and recessed into the assembly and all mirrors on the mirror assembly are compound mirrors.

FIG. 27 depicts an exemplary solar concentrator assembly utilizing asymmetric mirrors and entry facets along the solar axis where the opposing surfaces of the wave-guide assembly are parallel.

FIG. 28 presents a detailed drawing of a concentrator mirror segment and its relationship to the wave-guide segment.

FIG. 29 depicts an exemplary solar concentrator assembly utilizing asymmetric mirrors and entry facets along the solar axis where the opposing surfaces of the wave-guide assembly are converging.

FIG. 30 depicts an exemplary solar concentrator assembly where the width along the transverse axis is tapered.

FIG. 31A depicts an exemplary wave-guide assembly fabricated by extrusion.

FIG. 31B depicts a cross section of an exemplary component manufactured by extrusion.

FIG. 32A presents an isometric view of the principle components of an exemplary solar concentrator assembly.

FIG. 32B presents an isometric view of the assembled components of the exemplary solar concentrator assembly.

FIG. 32C presents a detailed view of a section of the mirror assembly affixed to the wave-guide assembly.

FIG. 32D provides an alternative view of selected components of a wave-guide assembly.

FIG. 33 presents a side view of an exemplary solar concentrator assembly utilizing elements such as holographic optical elements or diffractive optical elements as a concentrating component.

FIG. 34A presents a ray trace view of an exemplary solar concentrator assembly.

FIG. 34B presents details of how rays entering a rise facet refract because of the change in refractive index of the wave-guide material.

FIG. 34C presents an exemplary rise facet with a complex three-segment structure.

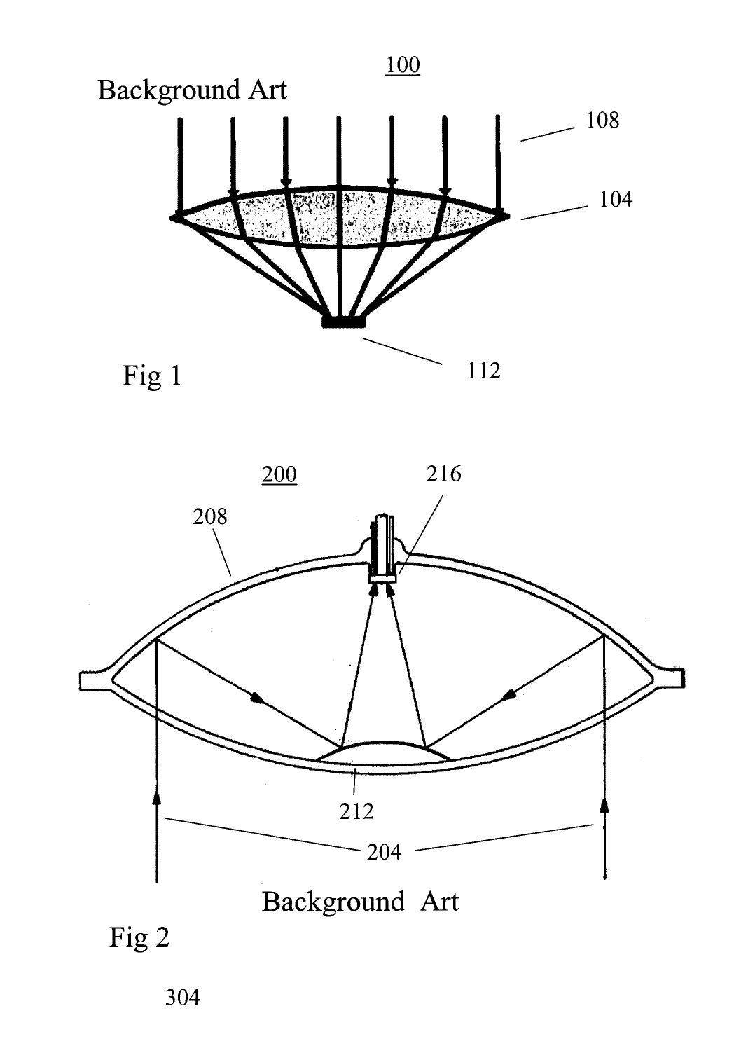

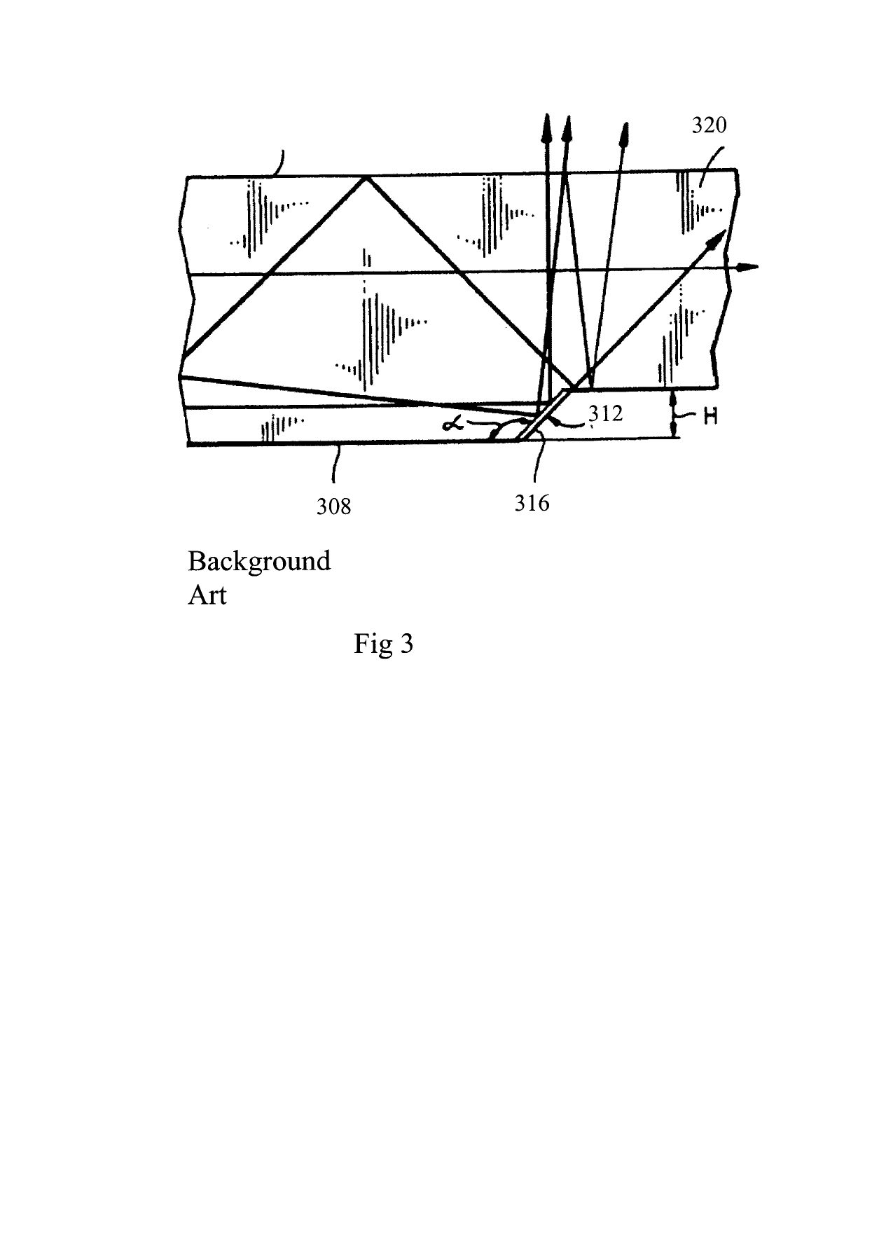

### DESCRIPTION OF THE INVENTION

In a pending provisional patent application 61/102,306 the inventors of this invention disclose many aspects of the design and fabrication of solar energy concentrators and components thereof, the contents whereof are incorporated into this application by reference in its entirety.

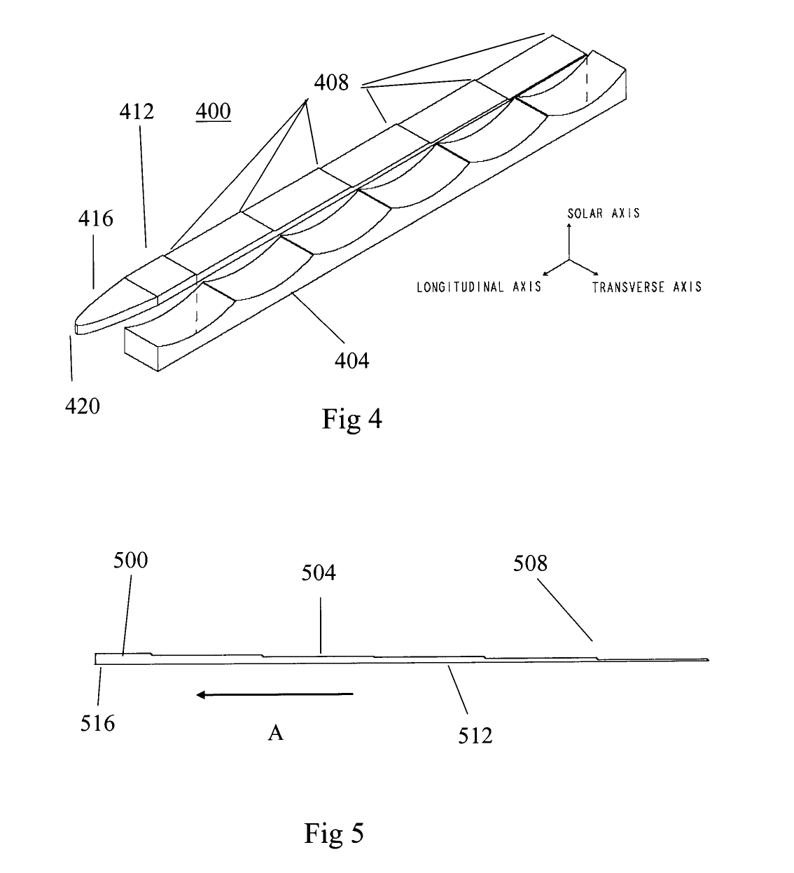

FIG. 4 depicts an embodiment of the solar concentrator 400 disclosed in this application. The concentrator 400 includes a mirror assembly 404 to collect and concentrate solar radiation and to direct it to a set of turn mirrors 408 affixed to a stepped wave-guide 412. The turn mirrors 408 are arrayed so as to receive the solar radiation from the mirror assembly 404 and to reflect the solar radiation into the stepped wave-guide 412 at least partially using TIR between a plurality of parallel surfaces. The stepped wave-guide 412 captures the light redirected by the turn mirrors 408 so that the light propagates in TIR mode to a target. A Simple Parabolic Concentrator (SPC) 416 is optionally installed at the end of the propagation path of the stepped wave-guide 412 to further concentrate the captured light. Finally, a photovoltaic converter (PVC) can be affixed to the stepped wave-guide 412 or to the optional SPC 416 at the PVC mounting position 420 to convert the concentrated solar radiation to electrical energy.

As shown in FIG. 4, three axes of the system are defined. The longitudinal axis is the long axis of the solar concentrator 400. The transverse axis is the axis across the surface of the solar concentrator 400 orthogonal to the longitudinal axis. The solar axis is the axis orthogonal to the longitudinal and transverse axes and therefore orthogonal to the upper and lower surfaces of the stepped wave-guide 412.

FIG. 5 depicts the side view of a stepped wave-guide 500 according to one embodiment of this invention. The stepped upper surface 504 and planar lower surface 512 are substantially parallel to each other. The stepped upper surface 504 includes a series of surfaces parallel to one another. The height of the step between each section is that which is needed to accommodate a turn mirror 508, preferably 1 mm, but the step height may be more or less depending on the particular design. As used herein, the term “upper” indicates that it is the side of the waveguide that faces the sun while the term “lower” indicates the side that is closest to the mirror assembly. Light propagates down the stepped wave-guide 500 in the direction of propagation indicated by arrow A to the exit end 516 of the stepped wave-guide 500.

The wave-guide 500 may be fabricated from an optical quality acrylic polymer material such as poly(methyl methylacrilate) (PMMA), commercially available as Plexiglas™ and in many other forms. Alternatively, it may be formed from a crown glass material such as Schott BK7. Both have refractive indices of approximately 1.50, which is the nominal refractive index used for optical materials in this application unless otherwise noted.

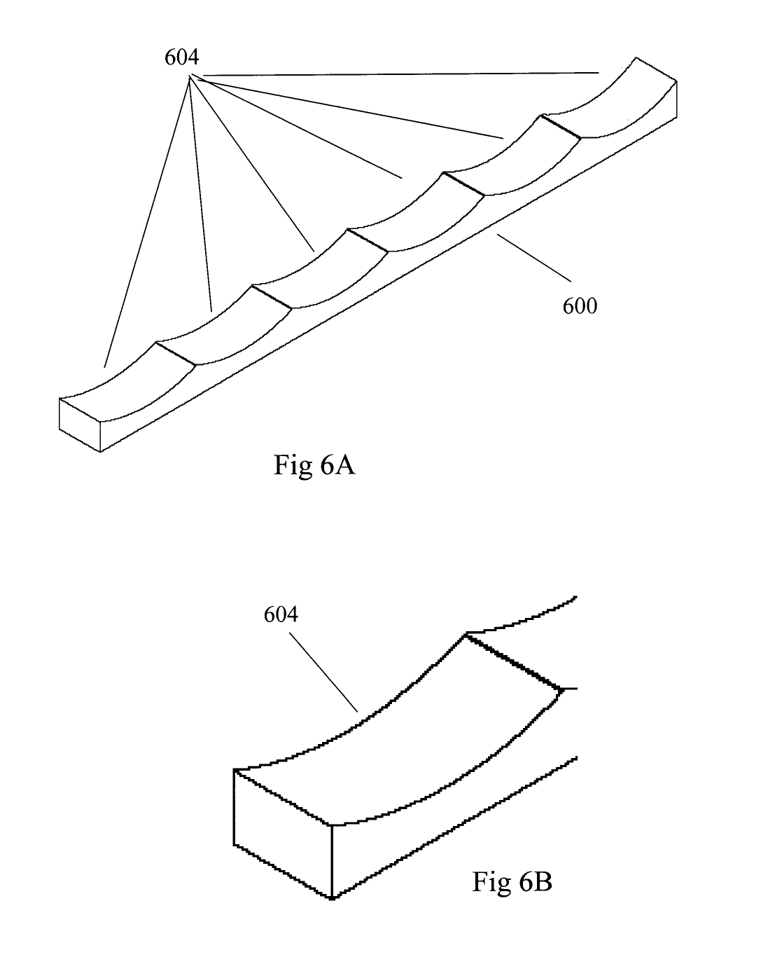

FIG. 6A is an isometric view of a mirror assembly 600. A typical mirror assembly 600 comprises a plurality of mirror segments 604, each of which may be designed and constructed to a different optical curvature.

Mirror assemblies may be fabricated in several ways. For example, they may be formed by injection molding or casting PMMA to the required optical shape and then evaporating aluminum or silver onto the resultant surface. Alternatively the surface can be coated by a set of dielectric thin-film coatings.

FIG. 6B is an isometric view of a trough mirror segment 604. The mirror curvature is oriented along the longitudinal axis and the non-curved mirror surface is oriented along the transverse axis. The radius of curvature of the mirror may vary across a single mirror segment. The focus of a trough mirror assembly will be a line coincident with the width of the assembly in the transverse direction. It is also possible that the curvature in one section of the mirror differs from the curvature in another section of the mirror.

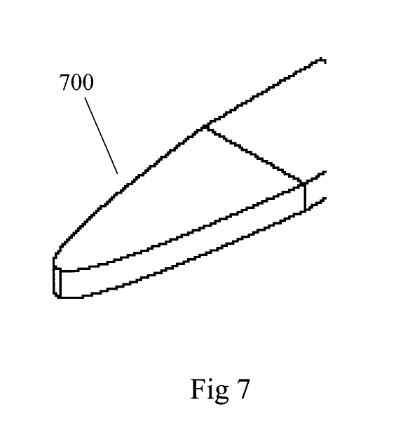

FIG. 7 is an isometric view of a Simple Parabolic Concentrator (SPC) 700. The SPC 700 is well known in the field of optics. The SPC 700 is able to collect light focused at or near infinity (collimated light) or light focused at some point beyond the SPC 700 and bring it to a relatively narrow point over a very short distance.

The SPC 700 may be fabricated from a crown glass material such as Schott BK7 to provide necessary heat handling capacity at the point where the solar energy achieves its highest level of concentration. At the required concentration levels the residual absorption losses from solar radiation in an SPC 700 fabricated from PMMA may cause the SPC 700 to change shape over time and therefore change its optical properties.

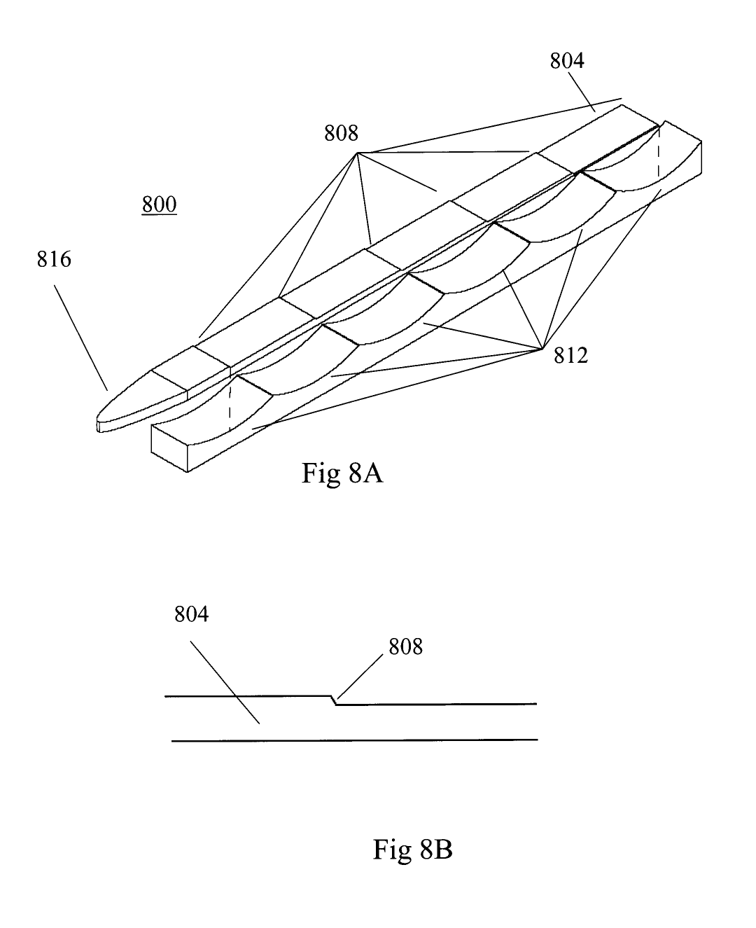

FIG. 8A depicts a first embodiment of the invention. The first embodiment comprises a solar concentrator 800 including a stepped wave guide 804 with turn mirrors 808 affixed thereto at approximately 45°, aspheric trough mirrors 812 with curvature on the longitudinal axis and no curvature on the transverse axis, and other incidental hardware suitable to assemble the unit. The trough mirrors 812 are designed and arrayed to focus solar energy in a line onto the turn mirrors 808, which are in turn designed so as to redirect the solar radiation to an angle at which it propagates within the wave-guide 804 by Total Internal Reflection (TIR) between the upper and lower surfaces of the wave-guide 804. Optionally the assembly includes a second level concentrator such as a Simple Parabolic Concentrator (SPC) 816 affixed to the wave-guide assembly 804 to further concentrate the solar radiation.

FIG. 8B depicts a side view of the wave-guide 804 noting the position of one of the turn mirrors 808 on the wave-guide 804. Other than the turn mirrors 808, the surfaces of the wave-guide 804 can be subjected to optical polishing sufficient to avoid significant surface scattering that might interfere with the TIR propagation but are otherwise uncoated. The wave-guide may optionally be coated with a thin-film coating to improve passage of light through the wave-guide to the mirror assembly without altering its TIR properties. Techniques for thin film coating are well known.

The description of the curvature of a mirror is based on the Surface Formula:

$$z = \frac{{cr}^{2}}{1 + \sqrt{1 - ( 1 + k ) {c}^{2} {r}^{2}}} + {\sum }_{i = 1}^{12} {α}_{i} {r}^{i}$$

wherein
z=height y-axis (dependent variable)
r=horizontal×axis (independent variable)
c=radius of curvature
k=conic constant
αᵢ=higher order constant
i=power of rⁱ associated with corresponding higher order constant

Optical CAD design and analysis software programs such as Zemax™, ASAP and Code V™ may receive data in this or similar formats and, through computational analysis, provide a detailed understanding of the important performance factors of an optical description such as optical efficiency (throughput), aberration, coma etc. Zemax™ may also calculate a solution based on programmed constraints.

In the present application (redirection and focusing of solar radiation) solar radiation is a distributed source subtended approximately 0.5° over a great distance, thus rendering the illumination effectively collimated. Calculations in Zemax™ and subsequent experimentation confirm that the effective focal distance of a reflective curved mirror is equal to c/2 or half the radius of curvature when the illumination is sufficiently collimated. In some instances the actual focal distance may be slightly shorter than the effective focal distance to overcome the effects of aberration.

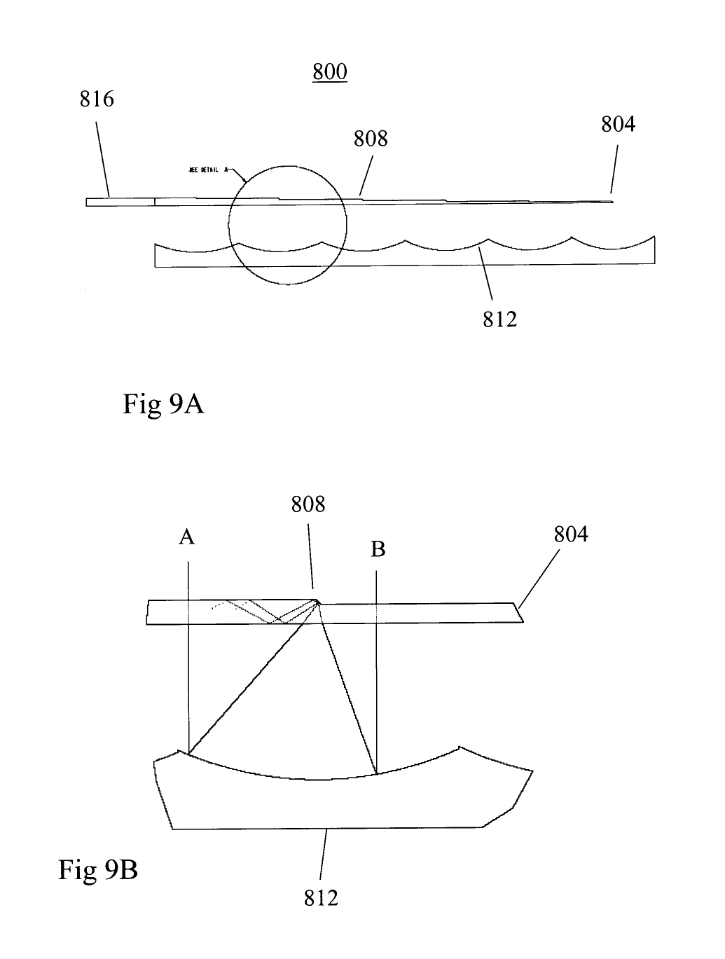

FIGS. 9A and 9B depict the opto-mechanical relationship between the aspheric trough mirrors 812 and the turn mirrors 808. FIG. 9A provides an overview of the concentrator assembly 800. The principle elements can be arrayed as shown. FIG. 9B provides a detailed exposition (Detail A from FIG. 9A) of the relative positions and optical function of the aspheric trough mirrors 812 and the turn mirrors 808 when illuminated by solar energy. The ray trace examples show how the surface of the mirror segment is designed so that the reflected solar energy (rays A, B) is focused in a line upon the turn mirror 808 for that segment.

The turn mirror 808 may be formed by placing reflective optical coatings such as silver, aluminum or a dielectric mirror on the angled surface. Deposition techniques suitable for this are well known in the state of the art. For example, the entire upper surface of the wave guide 804 may be coated with silver. The silver at the turn mirror 808 may be subsequently covered with a photo resist material using exposure and development processes similar to those used to fabricate printed circuit boards, thus allowing the silver material on the surfaces not covered by photo resist material to be removed by chemical means.

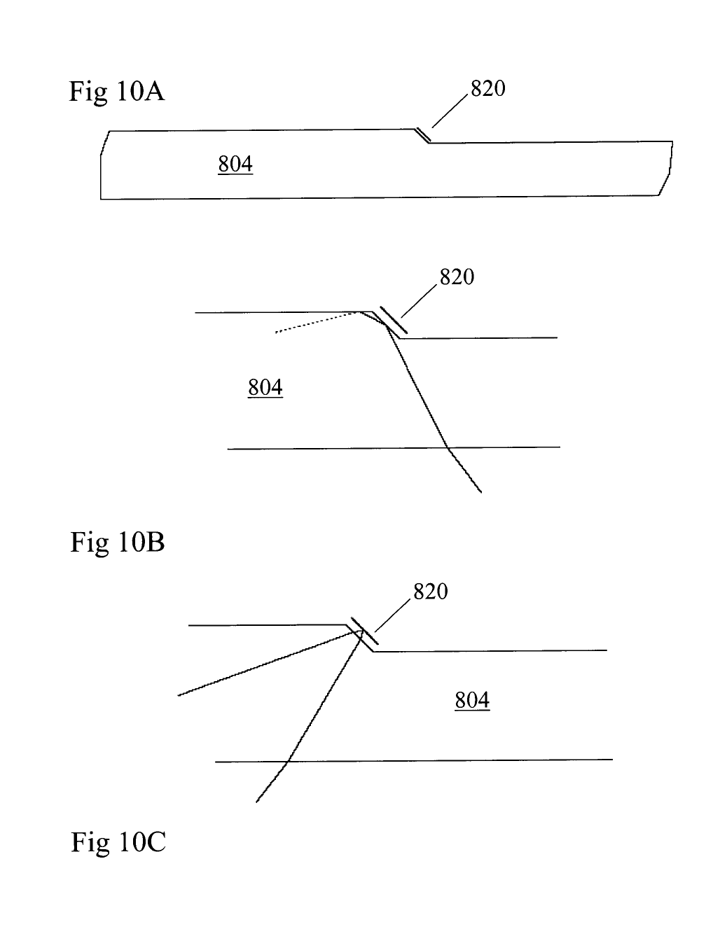

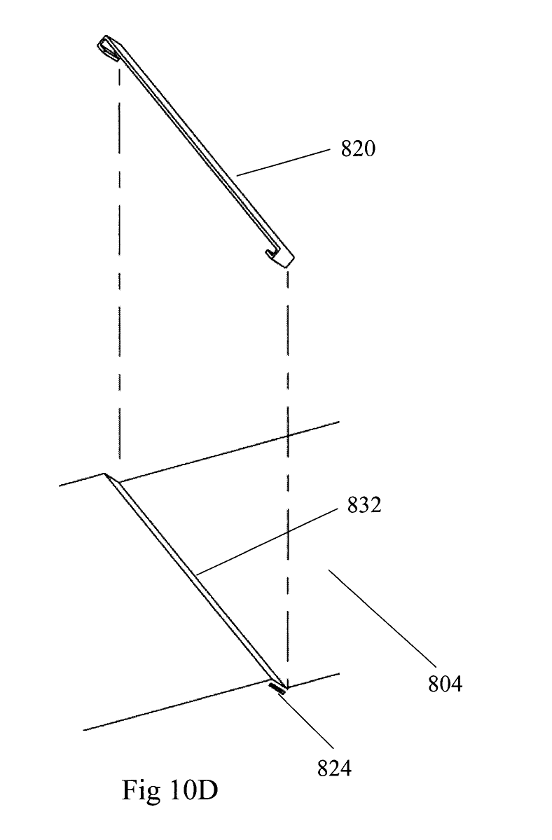

FIG. 10A depicts a wave-guide 804 including a variation on the turn mirror wherein an air gap separates the turn mirror 820 from the surface of the wave-guide, the turn mirror 820 otherwise being substantially parallel to the corresponding angled surface of the wave-guide 800. This variation takes advantage of the improved efficiency of a TIR reflection (100%) over first surface reflection from a highly efficient mirror (nominally 92-95% maximum). The gap between the mirror 820 and the angled surface of the wave-guide 804 need exceed only a few wavelengths of light for the mirror 820 not to interfere in the TIR reflection. A larger gap would normally be used for ease of manufacturing. Some solar radiation will satisfy the conditions for TIR and reflect off the angled surface of the wave-guide 804 adjacent to the turn mirror 820 while other solar radiation will not satisfy the conditions for TIR and will therefore pass through the angle surface and reflect off the turn mirror 820. FIG. 10B is a detailed drawing of a ray that reflects from the angle surface in TIR mode. The angle of incidence exceeds the critical angle relative to normal to the surface and thus satisfies the conditions for TIR. The critical angle for a beam of light within a material with a refractive index of 1.5 at its interface to air is 41.8° relative to the normal to the surface. FIG. 10C depicts a ray that is not reflected in TIR mode because it does not exceed the critical angle relative to the normal to the surface. In this mode the external minor 820 reflects the light and returns it to the wave-guide 804. FIG. 10D depicts a design to enable mounting of the turn mirror 820 onto the wave-guide 804. The wave-guide 804 is modified with slots 824 into which a flange formed on the turn mirror 820 can be inserted. Thus, the turn mirror 820 can be mounted at a predetermined distance from the angled surface 832 of the wave-guide 804. Other mechanical means of attachment are well known in the art. Additionally, such a turn mirror 820 can be mounted at a predetermined distance from an angled surface of the SPC 816.

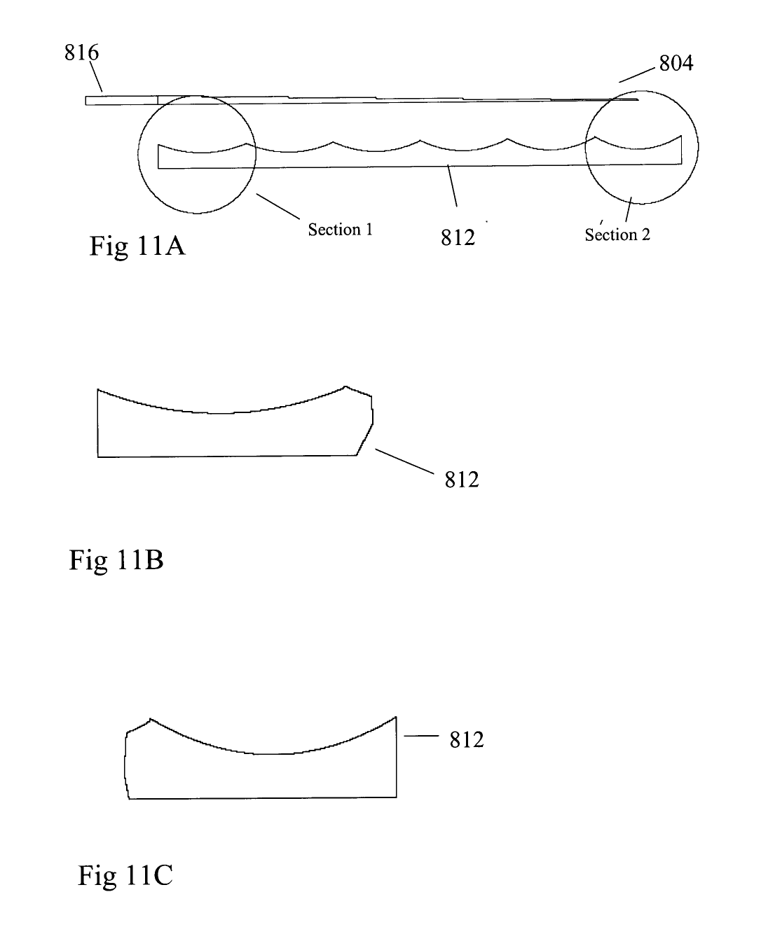

FIG. 11A illustrates that in the first embodiment the series of trough mirrors 812 depicted will not be identical. The optical path from each trough mirror 812 to its corresponding turn mirror 808 is slightly different because the thickness of the wave-guide 804 increases in the direction of the SPC 816. To achieve optimal focus on the turn mirror 808 it is therefore highly preferable that each trough mirror cross section has a slightly different shape. FIG. 11B and FIG. 11C are representative of the curvature relationship between two of the trough mirrors 812. FIG. 11B corresponds to the trough mirror 812 of Section 1 from FIG. 11A that is closest to the SPC 816 while FIG. 11C corresponds to the trough mirror 812 of Section 2 from FIG. 11A that is at the opposite end from the SPC 816. The radius of curvature depicted on FIG. 11C is significantly less than the radius of curvature of FIG. 11B, and the intervening mirrors 812 follow this same general relationship with each successive mirror 812 having a slightly smaller radius depending on its specific order in the sequence leading away from the SPC 816.

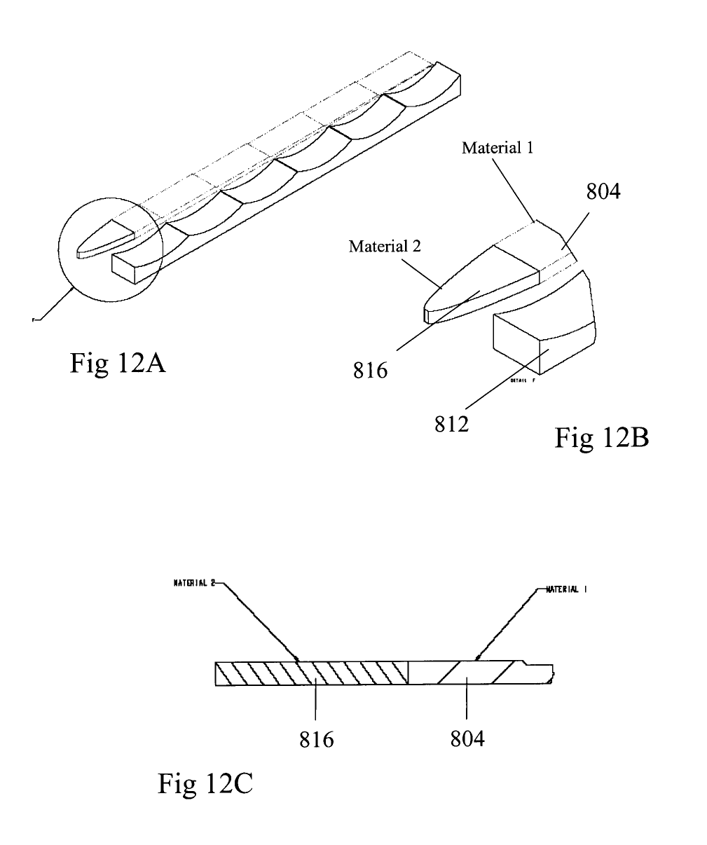

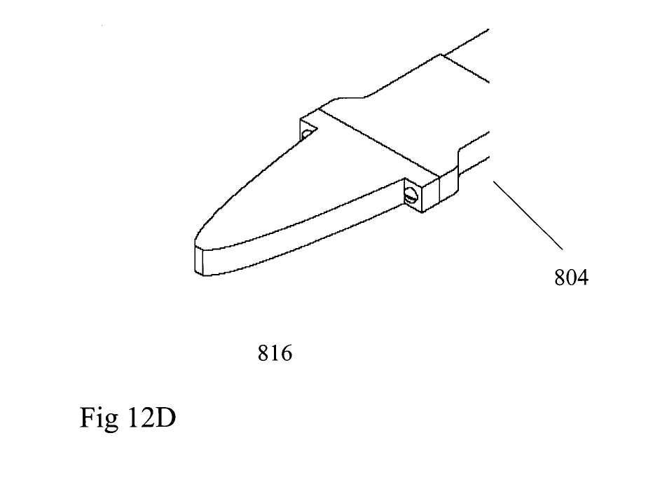

FIG. 12A depicts an exemplary position of the SPC 816 in relation to the wave-guide 804. FIG. 12B is an enlarged view of a section of FIG. 12A and calls out the materials used in the fabrication of the wave-guide 804 and the SPC 816. FIG. 12C depicts the materials to indicate that the SPC 816 and the wave-guide 804 need not be fabricated from the same type of material. For example, the wave-guide 804, noted as Material 1, may be fabricated from an optical quality acrylic polymer material such as poly (methyl methylacrilate) (PMMA), commercially available as Plexiglas, while Material 2 (the SPC 816) may be fabricated from a crown glass material such as BK7 to provide necessary heat handling capacity at the point where the solar energy achieves its highest level of concentration. Note that the effective indices of refraction of the two cited materials are similar at approximately 1.49 and 1.51 respectively, thus simplifying the optical mating of the materials. An optical system using two or more different materials with coefficients of thermal expansion (C_{TE}) that vary significantly must be designed so as to assure that the components are in the correct optical arrangement when the device is at nominal operating temperature.

FIG. 12D presents one example of a mounting mechanism that mates the wave-guide 804 to the second level concentrator (SPC 816) along the transverse axis of the wave-guide 804. This method of mounting avoids interfering in the TIR method of propagation because in the first embodiment TIR predominantly takes place in the solar axis direction within the wave-guide 804 and incidentally in the transverse axis direction of the wave-guide 804. Mated mounting flanges 840 are formed on either side of the SPC 816 and the wave guide 804 and they are then attached to one another by fastening means 844 such as a common screw.

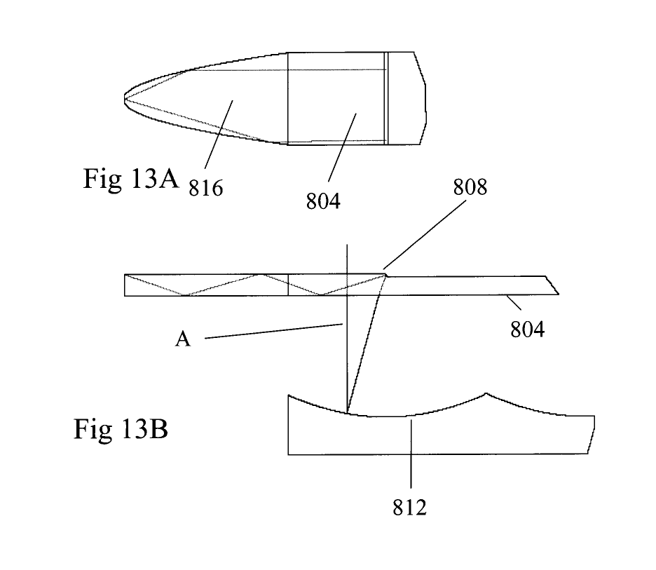

FIG. 13A depicts a partial ray trace A along the longitudinal axis within the wave-guide 804 that passes into the SPC 816 as viewed from the solar axis. The light does not TIR substantially between the lateral surfaces of the wave-guide 804 and SPC 816 assemblies until it enters the SPC 816. FIG. 13B depicts a partial ray trace as seen from the transverse axis of the system. The light propagates down the longitudinal axis by TIR between the upper and lower surfaces of the wave-guide 804 and the SPC 816.

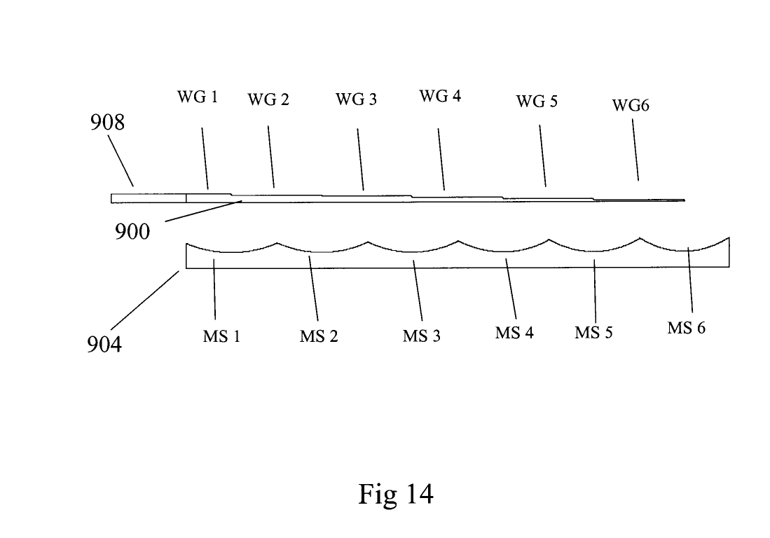

In a series of simulations of the first embodiment exemplary, parameters for an implementation were defined. A series of wave-guide segments (WG1-WG6) of an exemplary wave-guide assembly 900 and a series of trough mirror segments (MS1 to MS6) of an exemplary mirror assembly 904 are identified in FIG. 14 for cross-reference to various tables describing these features in the present application. The exemplary wave-guide 900 shown in FIG. 14 has an SPC 908 on an exit end thereof.

The mirror assembly 904 for a simulation implementing the first embodiment is presented in the following data table.

| | | | Radii of curvature | | | |
|---|---|---|---|---|---|---|
| | Dimensions (mm) | | (mm) | | | |
| Mirror | Longi- | Trans- | Trans- | Longi- | Conic | αᵢ |
| Segment | tudinal | verse | verse | tudinal | Constant | values |
| MS 1 | 60 | 25 | ∞ | 74.379 | −0.7860 | All = 0 |
| MS 2 | 60 | (Arbitrary | ∞ | 73.035 | −0.8230 | All = 0 |
| MS 3 | 60 | but affects | ∞ | 71.691 | −0.8127 | All = 0 |
| MS 4 | 60 | SPC size) | ∞ | 70.348 | −0.9000 | All = 0 |
| MS 5 | 60 | | ∞ | 69.000 | −0.9400 | All = 0 |
| MS 6 | 60 | | ∞ | 67.666 | −0.9806 | All = 0 |

All mirror segments in this example have identical external dimension of 60 millimeters (mm) longitudinally by 25 mm in the transverse direction. The 25 mm transverse dimension is selected to insure the dimensions of the SPC are reasonable. Subsequent data on the corresponding wave-guide segment will show that the mirror position over MS 1 is 5 mm further from the center of the mirror than the corresponding position over MS 6 and that is reflected in the change to the radius of curvature across the mirror assembly 904. The center of each mirror segment in the mirror assembly is nominally 33.5 mm from the bottom of the wave-guide assembly 900. Use of added components αᵢ in the surface formula to correct for aberration proved unnecessary in this series of simulations. However, it is foreseeable that some of these components may be needed in alternative implementations according to this invention.

The wave-guide assembly 904 for this implementation is described in the following table.

| | Segment | | Thickness |
|---|---|---|---|
| Segment | longitudinal | Transverse | (solar axis) |
| Number | length (mm) | width (mm) | (mm) |
| WG 1 | 30 | 25 (match | 6 |
| WG 2 | 60 | mirror | 5 |
| WG 3 | 60 | assembly) | 4 |
| WG 4 | 60 | | 3 |
| WG 5 | 60 | | 2 |
| WG 6 | 60 | | 1 |

The thickness along the solar axis increases by 1 mm at each turn mirror. In order to be fully efficient in capturing the reflected solar radiation, the trough mirrors have a width in the transverse direction that matches the width of the wave-guide in the transverse direction.

The spatial relationship between the turn mirrors and the mirror segments of the mirror assembly 904 places the center of each mirror underneath the corresponding turn mirror. The spatial distance from the center of each mirror to the bottom of the wave-guide assembly 900 in this example is fixed at 33.5 mm. In an alternative embodiment, the distance from the center of each mirror segment of the mirror assembly to the corresponding turn mirror could be constant.

Therefore, the distance from the center of each mirror segment to the corresponding turn mirror differs by 1 mm from the adjacent mirror-pairs. The following table describes the information. Note that the center of the angled surface of each turn mirror is midway between the adjacent stepped surfaces.

| | Distance to | Distance to | |
|---|---|---|---|
| | Bottom of | Center of Turn | Nominal Focal |
| Mirror Segment | Wave-guide | Mirror | Distance |
| MS 1 | 33.5 | 39.0 | 37.2 |
| MS 2 | | 38.0 | 36.5 |
| MS 3 | | 37.0 | 35.9 |
| MS 4 | | 36.0 | 35.2 |
| MS 5 | | 35.0 | 34.5 |
| MS 6 | | 34.0 | 33.83 |

The thickness of the wave-guide with its higher refractive index is not optically significant. The difference between the actual distance to the turn mirror and the nominal focal distance (defined as the radius of curvature divided by 2 when the light is collimated) is an alternative solution to the issue of aberration.

The specification for the SPC 908 is determined by specific performance criteria required for its performance. Thus, it is beneficial for the SPC 908 to collect all the light exiting the wave-guide or at least a high percentage. The shape of the SPC 908 is a parabola truncated at its vertex so that the focal point of the parabola is located at the mid-point of the exit aperture. The formula for a parabola with vertex located at the intersection of the x and y coordinate systems is

y=x²/(4f)

where f is the focal distance, x is the axis of input/output and y is the axis of the length.

The exit aperture Xₒᵤₜ is calculated from the preceding formula to be 2f wide. The input aperture is defined as required to capture the output of the wave-guide assembly 900, that being 25 mm in the present example. The geometrical concentration of an SPC 908 is defined as Xᵢₙ=concentration×Xₒᵤₜ. Given a desired concentration ratio of 20 and the preceding 25 mm value for Xᵢₙ the resultant value for Xₒᵤₜ is 1.25 mm. From these numbers and the formula for a parabola the length required to achieve that input aperture and concentration ratio is 250 mm. The calculated values are summarized in the following table.

| Parameter | Value |
|---|---|
| X_{IN} (Input aperture) | 25 mm |
| X_{OUT} (Output aperture) | 1.25 mm |
| Length (longitudinal) | 250 mm |
| Geometrical concentration | 20 |

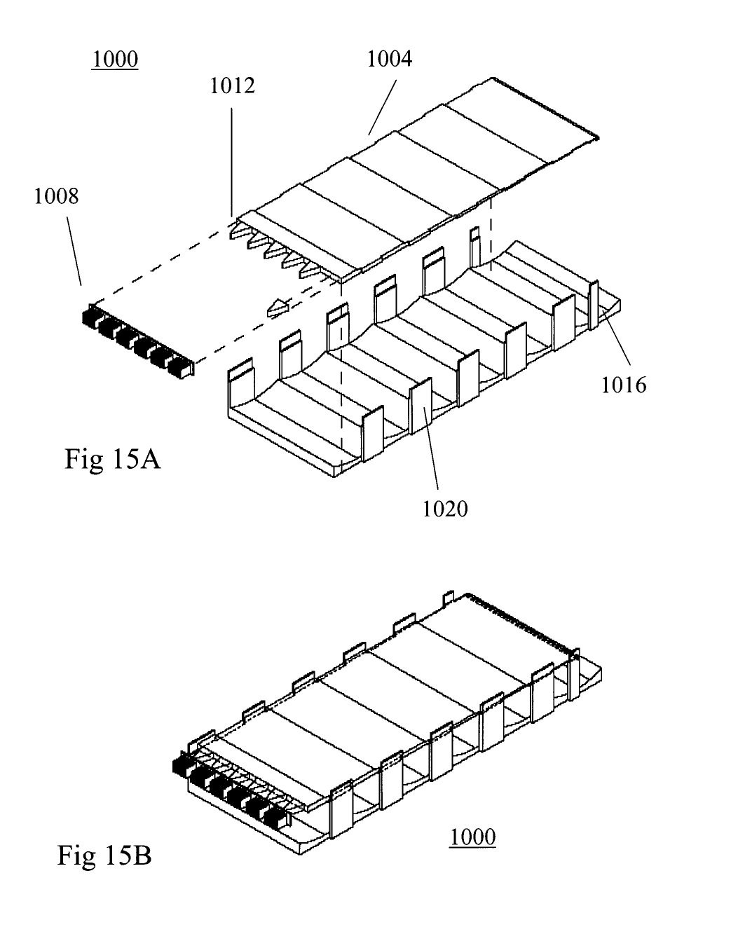

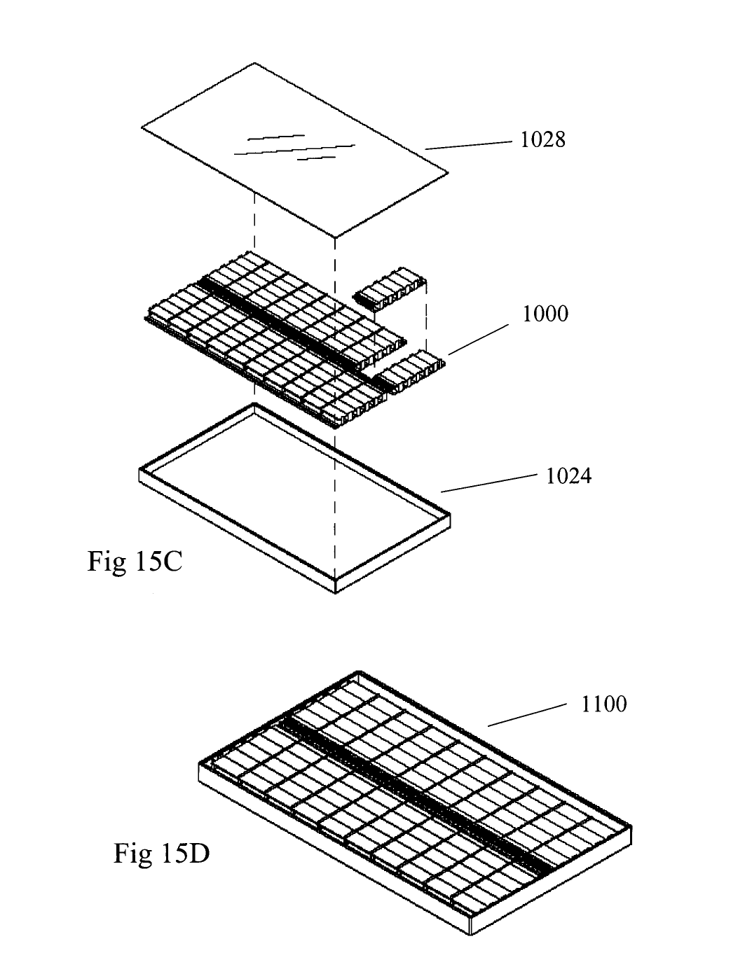

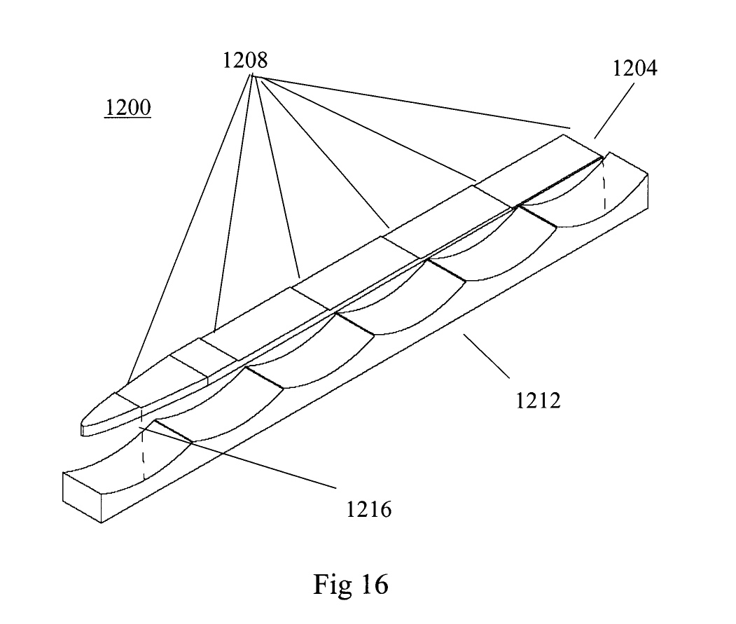

FIG. 15A depicts a blow up isometric view of an exemplary solar energy concentrator assembly 1000 formed by an array of solar energy concentrator devices. The boundaries between each individual wave-guide 1004 are not shown. The elements are aligned so that the photovoltaic converters 1008 are mounted at the end of the SPC 1012. FIG. 15B depicts an isometric view of an assembled solar energy concentrator assembly 1000 comprising the individual elements depicted in FIG. 9A. In FIG. 15B, the wave-guides 1004 are attached to the trough mirrors 1016 by connecting plates 1020. FIG. 15C depicts a blow up isometric view of a plurality of solar energy concentrator assemblies 1000 and its associated components to protect it from the elements. The plurality of solar energy concentrator assemblies is inserted into a weather cover frame 1024 and a transparent weather cover 1028 is attached thereto. FIG. 15D presents the weatherproof solar energy assembly 1100 based on the components of FIG. 15A and FIG. 15C.

In a preferred implementation the entire array is mechanically steered so that the solar energy illuminating the device is approximately normal to the stepped surface of the light guide. Such steering systems are well known in the art.

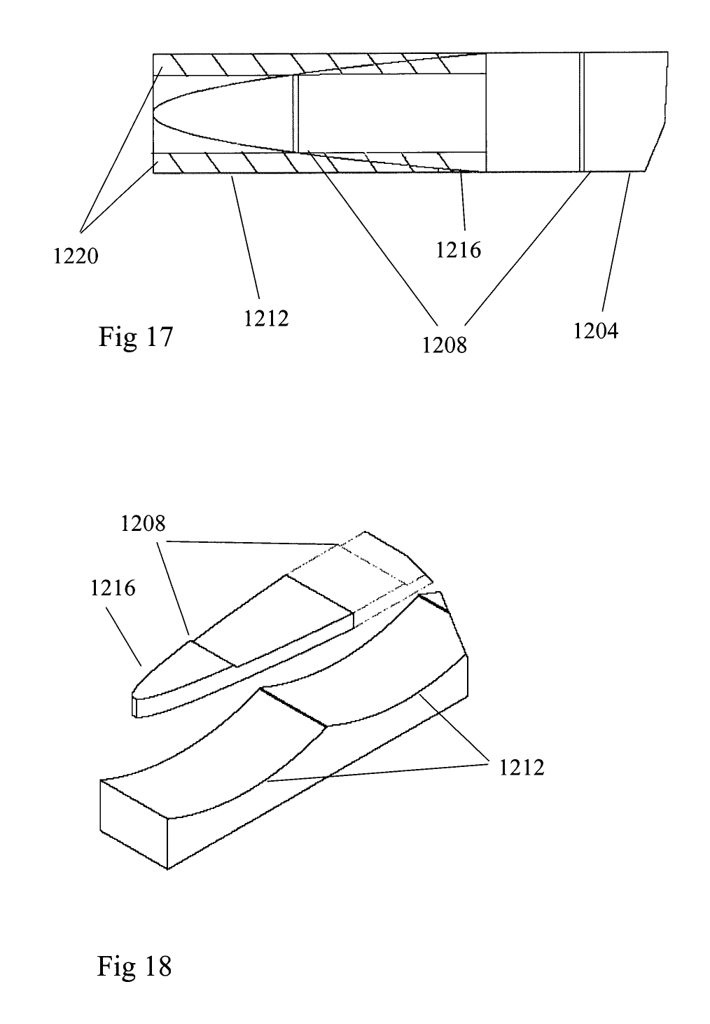

FIG. 16 depicts a second embodiment of a solar concentrator 1200 of the present invention. In this embodiment the relationship between the wave-guide 1204, the simple parabolic concentrator 1216 and the trough mirror assembly 1212 is modified so that the transition from the wave-guide assembly 1204 to the simple parabolic concentrator 1216 occurs in the area over the trough mirror assembly 1212. The 250 mm SPC length noted in the first embodiment is significant compared to the overall 360 mm length of the other components in the system. This approach sacrifices some efficiency in one sense, as discussed below with respect to FIG. 17, but permits a decrease in the overall length of the full assembly. In an installation where the total size is constrained, such as a rooftop, this modest sacrifice of efficiency may result in greater total output due to the decreased footprint of the individual components of the system. Stated otherwise, the collecting area in the second embodiment may cover a higher percentage of the roof than in the first embodiment, and thus more of the solar energy impinging on the roof may be captured. The trough mirror assembly 1212 is otherwise unchanged from the first embodiment.

FIG. 17 presents a top view depicting the areas (shaded) adjacent to the SPC 1216 where the assembly of FIG. 10 cannot collect and capture solar energy. Solar energy passing through the shaded areas 1220 is reflected back and not collected as this light is not focused on a turn mirror. However, this arrangement still permits the capture of more solar energy than in embodiment 1 which has no trough mirrors 1212 under the SPC 1216.

FIG. 18 presents an isometric projection of the same features noted in FIG. 17 that depicts the spatial relationship between the trough mirrors 1212, the turn mirrors 1208 and the SPC 1216. The SPC 1216 in this case is depicted as approximately the length of a mirror segment on the trough mirror assembly 1212. A turn mirror 1208 and corresponding thickness change comprise modified features of the SPC 1216.

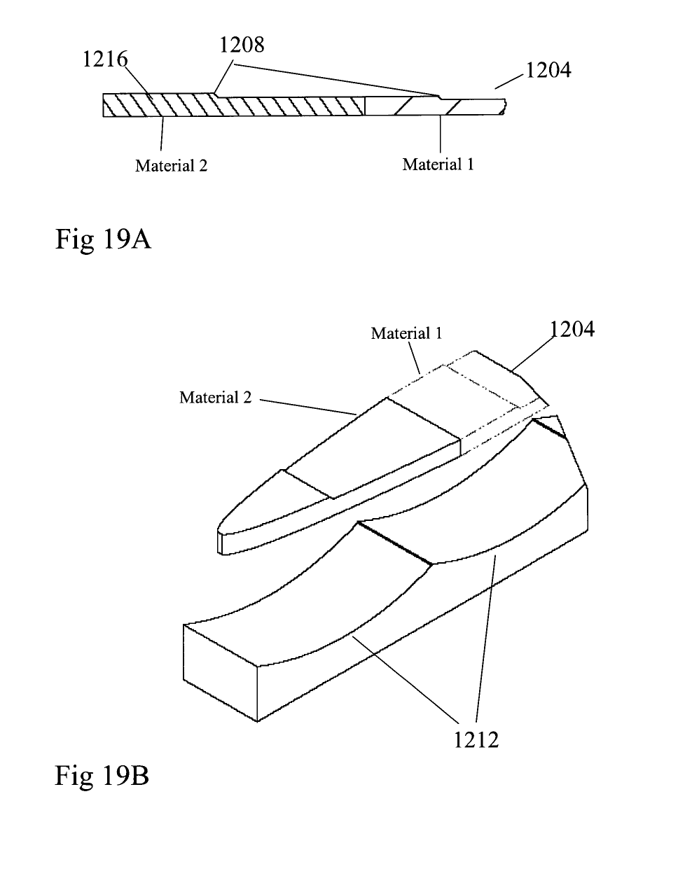

FIG. 19A provides a side view of the SPC 1216 and a section of the wave-guide 1204 with the two materials noted. Material 1 in the wave-guide section 1204 may be any suitable optical material including PMMA. Material 2 in the SPC section 1216 may be any suitable material including a crown glass material such as BK7 selected for its heat handling capacity. Material 1 and material 2 may in fact be the same material and the entire assembly may be made as a single piece without need for a seam. Turn mirrors 1208 may be formed in either of the sections of the assembly, as noted. Attachment of the SPC 1216 to the wave-guide 1204 may be made using conventional methods such as utilizing an adhesive layer to match the two. Alternatively the flange method of FIG. 12D may be used. FIG. 19B presents an isometric view of the assembly of FIGS. 16-19A including trough mirrors 1212 for additional clarity.

Other features of this second embodiment do not differ significantly from the first embodiment. In an example of the second embodiment, the specification for the mirror assembly and its individual mirror segment descriptions may be unchanged from the exemplary data presented for the first embodiment. The turn mirror arrangement presented in FIGS. 9A and 9B may be applied in this embodiment without change except as previously noted. The spacing between turn mirrors remains unchanged in a modeled example from the 60 mm previously presented. The alternative turn mirror arrangement of FIGS. 10A, 10B, 10C and 10D may be applied without change. The magnification considerations related to the curvature of the trough mirrors are also unchanged from FIGS. 11A, 11B and 11C. The ray trace and TIR consideration depicted in FIGS. 13A and 13B are unchanged in this embodiment. The assemblies can be ganged together in a manner similar to the method previously shown in FIGS. 15A, 15B, 15C and 15D.

The table of descriptive data for an exemplary mirror assembly according to the first embodiment applies to this example of the second embodiment. The following tables describe an implementation of the wave-guide and SPC based on an SPC with a concentration ratio of approximately 5. The data for the wave-guide follows. Note that Segment 1 is completely replaced by the recessed SPC as well as part of Segment 2.

| | | | Thickness |
|---|---|---|---|
| Segment | Segment length | Transverse | (solar axis) |
| Number | (mm) | width (mm) | (mm) |
| 1 | Not applicable | | |
| 2 | 27.5 | 25 | 5 |
| 3 | 60 | | 4 |
| 4 | 60 | | 3 |
| 5 | 60 | | 2 |
| 6 | 60 | | 1 |

The data for the SPC follows.

| Parameter | Value |
|---|---|
| X_{IN} (Input aperture) | 25 mm |
| X_{OUT} (Output aperture) | 5 mm |
| Length (longitudinal) | 62.5 mm |
| Turn mirror position | 30 mm |
| (from output aperture) | |
| Turn Mirror width | 17 mm |
| (SPC width) | |
| Thickness (at input aperture) | 5 mm |
| Thickness (at exit aperture) | 6 mm |
| Geometrical concentration | 5 |

Note that a low concentration ratio does not necessarily indicate a lower output as a larger PVC may be used. The issue is primarily one of cost.

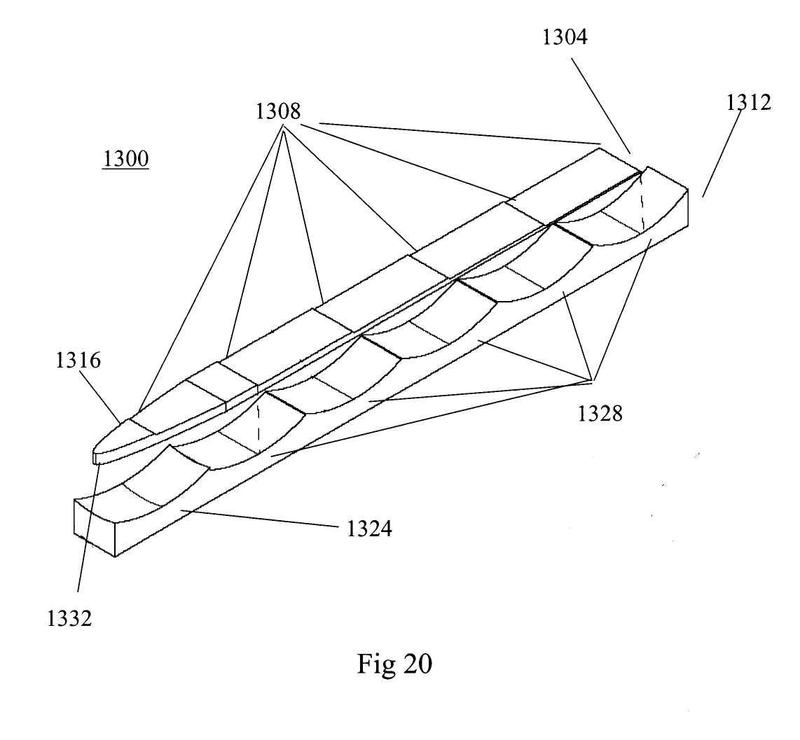

FIG. 20 depicts a third embodiment of a solar concentrator 1300 of the present invention. In this embodiment the SPC 1316 is again substantially retracted to the extent of the underlying mirror assembly 1312. However, the issue of efficiency loss described above for the second embodiment is substantially eliminated though a modification to the mirror assembly 1312. The mirror section 1324 of the mirror assembly 1312 underlying the recessed SPC 1316 may be constructed with spherical, parabolic, or any other suitable curvature along the transverse direction while retaining the aspheric shape along the longitudinal axis. The focal point of the curved mirror section 1324 along the transverse axis is located approximately at the photovoltaic cell (to be mounted at the PVC mounting point 1332) while the focal point of the mirror cross section is a line coincident with the turn mirror 1308 corresponding to that mirror section 1324. The sections 1328 of the mirror assembly 1312 underlying the full width wave-guide 1304 may be retained as trough mirrors. The sections with gain along the transverse axis are referred to as compound mirrors.

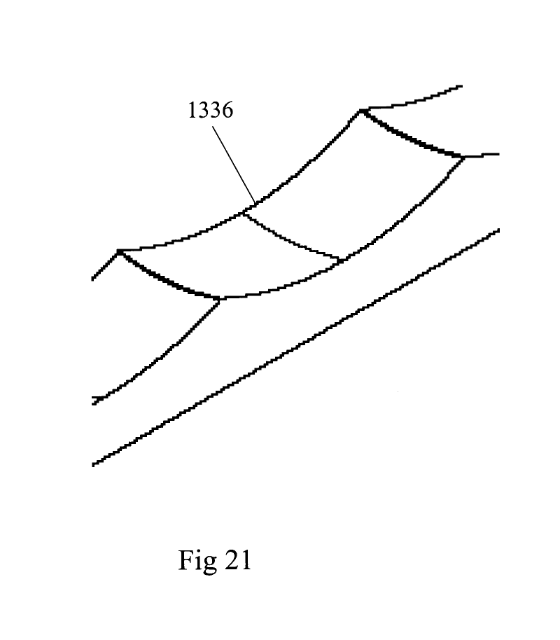

FIG. 21 presents an exemplary compound mirror 1336 as discussed above. The mirror 1336 is designed with curvature on the longitudinal axis as is the case in the trough mirror 1328 and also has curvature on the transverse axis. It is also possible that the curvature in one section of the mirror differs from the curvature in another section of the mirror.

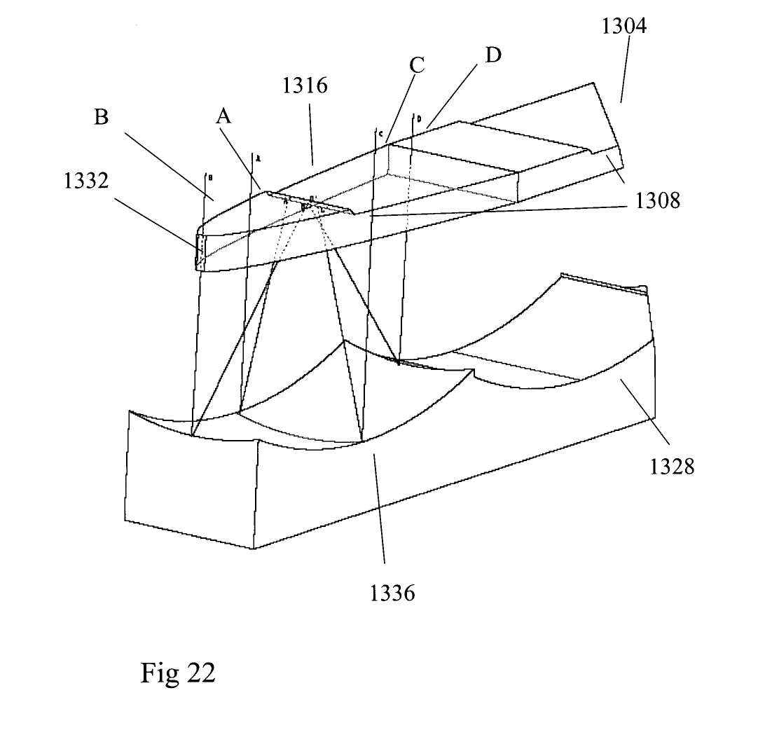

FIG. 22 depicts a ray trace of a compound mirror segment 1336 underneath a SPC 1316. Incident solar energy at the extremes along the central longitudinal axis (rays B, D) pass through the SPC 1316 to the mirror 1336 and then are reflected onto the turn mirror 1308. Incident solar energy at the extremes of the transverse axis (rays A, C) do not pass through the SPC 1316 but are reflected onto the turn mirrors 1308 with some level of gain since the transverse axis of the compound mirror 1336 is wider than the turn mirror 1308 on the SPC 1316. The focal point of the transverse section of the compound mirror 1336 is the photovoltaic converter to be mounted at the PVC mounting point 1332 at the end of the SPC 1316 as previously shown in FIG. 15A. Alternatively a focal point may be chosen that ensures that all the solar radiation thus reflected enters the SPC with angles suitable for TIR without substantial regard for the PVC mounting point (not shown).

Other features of this third embodiment do not differ significantly from the first embodiment. The turn mirror arrangement presented in FIGS. 9A and 9B may be applied in this embodiment without change except as previously noted. The alternative turn mirror arrangement of FIGS. 10A, 10B, 10C and 10D may be applied without change. The magnification considerations related to the curvature of the trough mirrors are also unchanged from FIGS. 11A, 11B and 11C. The ray trace and TIR consideration depicted in FIGS. 13A and 13B are unchanged in this embodiment. The assemblies can be ganged together in a manner similar to the method previously shown in FIGS. 15A, 15B, 15C and 15D.

The following tables present data for an implementation of this embodiment. The mirror assembly is defined by the following data for use with the surface formula presented elsewhere in this document.

| | | | Radii of curvature | | | |
|---|---|---|---|---|---|---|
| | Dimensions (mm) | | (mm) | | | |
| Mirror | Longi- | Trans- | Trans- | Longi- | Conic | αᵢ |
| Segment | tudinal | verse | verse | tudinal | Constant | values |
| MS1 | 60 | 25 | 130-170 | 74.379 | −0.7860 | All = 0 |
| MS 2 | 60 | (Arbitrary | ∞ | 73.035 | −0.8230 | All = 0 |
| MS 3 | 60 | but affects | ∞ | 71.691 | −0.8127 | All = 0 |
| MS 4 | 60 | SPC size) | ∞ | 70.348 | −0.9000 | All = 0 |
| MS 5 | 60 | | ∞ | 69.000 | −0.9400 | All = 0 |
| MS 6 | 60 | | ∞ | 67.666 | −0.9806 | All = 0 |

The curve for Mirror Segment 1 on the transverse axis is spherical. Although the αᵢ values are 0 in this implementation it is anticipated that other implementations may require use of these constants in order to define a fully optimal mirror surface definition, The wave-guide assembly and SPC are identical to that of the second embodiment.

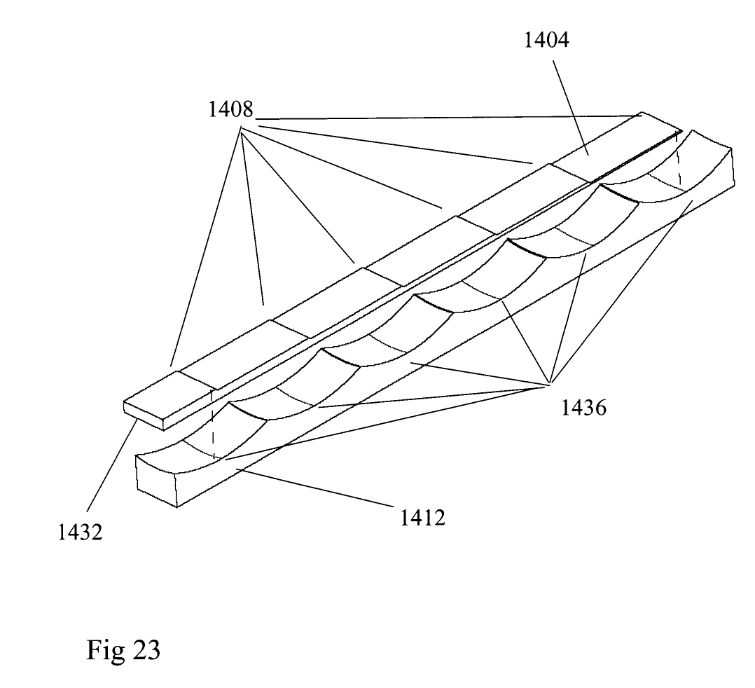

FIG. 23 presents a fourth embodiment of a solar concentrator 1400 of the present invention. In this embodiment the significant change is that all mirrors in the mirror assembly 1412 are now compound mirrors 1436. The compound mirrors 1436 have an aspheric curvature along the longitudinal axis and a spherical curvature along the transverse axis. The focal points of the mirrors 1436 along the longitudinal axis are the turn mirrors 1408 located above each mirror 1436. The focal point of all mirrors 1436 on the transverse axis is now the photovoltaic converter to be mounted directly at the PVC mounting point 1432 at the end of the wave-guide 1404. This focus simplifies the construction of a system although it requires additional care in the choice of materials for the wave-guide 1404 because of thermal heating that may take place at the focal point. If thermal heating becomes an issue the entire wave-guide 1404 may be manufactured from crown glass rather than PMMA.

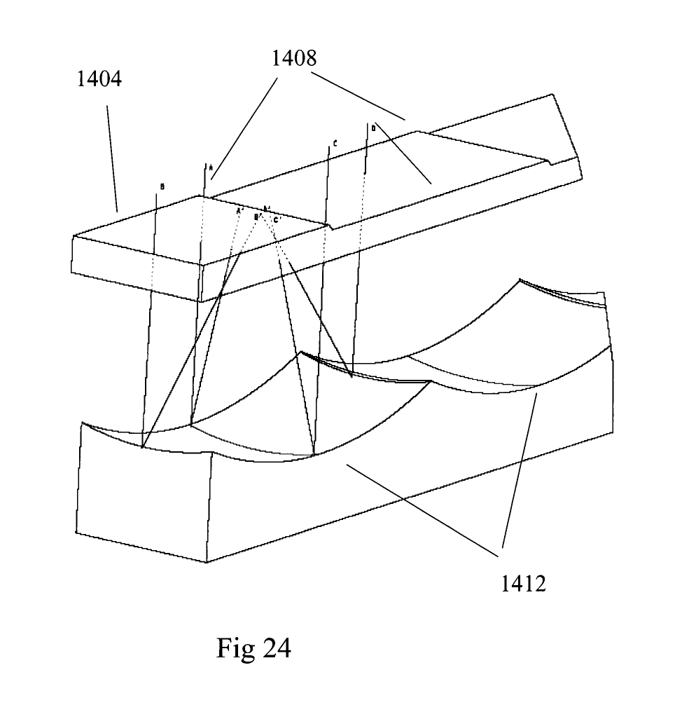

FIG. 24 presents a ray trace depicting the interaction of a compound minor segment 1436 with the corresponding wave-guide 1404 and turn mirror segment 1408. All minor segments 1436 have curvature along the transverse axis with the degree of curvature related to its distance from the photovoltaic converter. Accordingly, incident solar energy at the extremes along the central longitudinal axis (rays B, D) and at the extremes of the transverse axis (rays A, C) pass through the wave-guide 1404 to the mirror 1412 and then are reflected as reflected rays A'-D′ onto the turn minor 1408

The following table presents data on an implementation of this embodiment.

| | | | Radii of curvature | | | |
|---|---|---|---|---|---|---|
| | Dimensions (mm) | | (mm) | | | |
| Mirror | Longi- | Trans- | Trans- | Longi- | Conic | αᵢ |
| Segment | tudinal | verse | verse | tudinal | Constant | values |
| 1 | 60 | 25 | 130-170 | 74.379 | −0.7860 | All = 0 |
| 2 | 60 | | 240-280 | 73.035 | −0.8230 | All = 0 |
| 3 | 60 | | 260-380 | 71.691 | −0.8127 | All = 0 |
| 4 | 60 | | 420-480 | 70.348 | −0.9000 | All = 0 |
| 5 | 60 | | 450-530 | 69.000 | −0.9400 | All = 0 |
| 6 | 60 | | 460-610 | 67.666 | −0.9806 | All = 0 |

Although the αᵢ values are all zero in this example it is anticipated that some values may be other than zero in other implementations.

The following table presents information relating to the wave-guide assembly.

| Segment | Segment length | Transverse | Thickness (solar |
|---|---|---|---|
| Number | (mm) | width (mm) | axis) (mm) |
| 1 | 30 | 25 (may be | 6 |
| 2 | 60 | narrower or | 5 |
| 3 | 60 | tapered | 4 |
| 4 | 60 | depending on | 3 |
| 5 | 60 | exact light | 2 |
| 6 | 60 | path) | 1 |

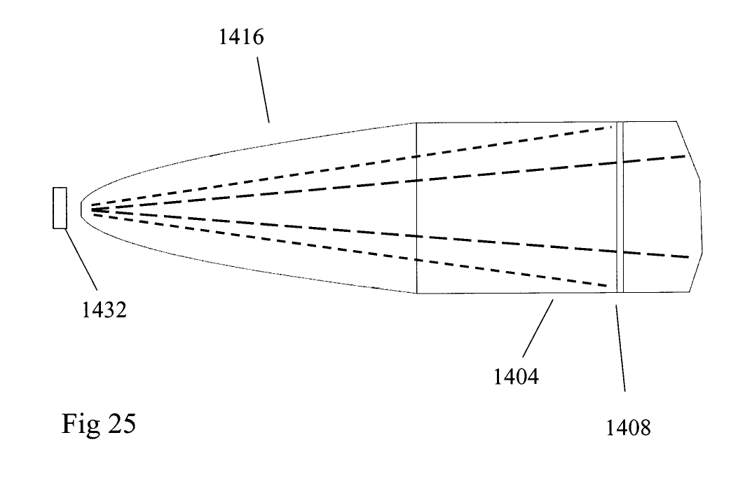

In an alternative implementation of the fourth embodiment an SPC 1416 may be attached at the point shown for the mounting point for the PVC 1432 (PVC not shown). FIG. 25 provides a ray trace of the concentrated light within the SPC 1416 as viewed from above. This enables further concentration of the light with a relatively short SPC 1416 as the light is already substantially concentrated by the transverse curvature of the mirrors 1436. One implementation from simulation is presented.

| Parameter | Value |
|---|---|
| X_{IN} (Input aperture) | 10 mm |
| X_{OUT} (Output aperture) | 0.5 mm |
| Length (longitudinal) | 100 mm |
| Thickness | 6 mm |
| Geometrical concentration | 20 |

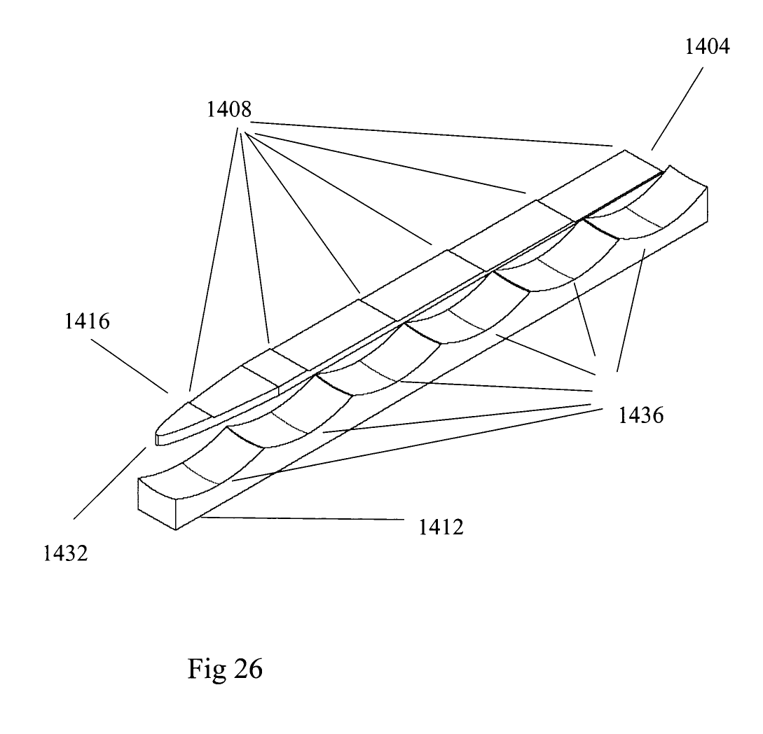

FIG. 26 depicts an additional alternative implementation of the fourth embodiment that includes the SPC 1416 implementation of embodiment 2 and embodiment 3 that includes a turn mirror 1408 on the SPC 1416.

Other features of this fourth embodiment do not differ from the first embodiment. The turn mirror arrangements presented in FIGS. 9A and 9B may be applied in this embodiment without change. The alternative turn mirror arrangement of FIGS. 10A, 10B, 10C and 10D may be applied without change. The assemblies can be ganged together in a manner similar to the method previously shown in FIGS. 15A, 15B, 15C and 15D. In an alternative implementation of this embodiment the mirror assembly may possess additional mirror segments along the transverse axis (not shown) that interact with a single wave-guide or multiple wave-guides wherein each longitudinal mirror/wave-guide set interacts with a separate SPC. An array after this implementation would be similar to FIG. 15B.

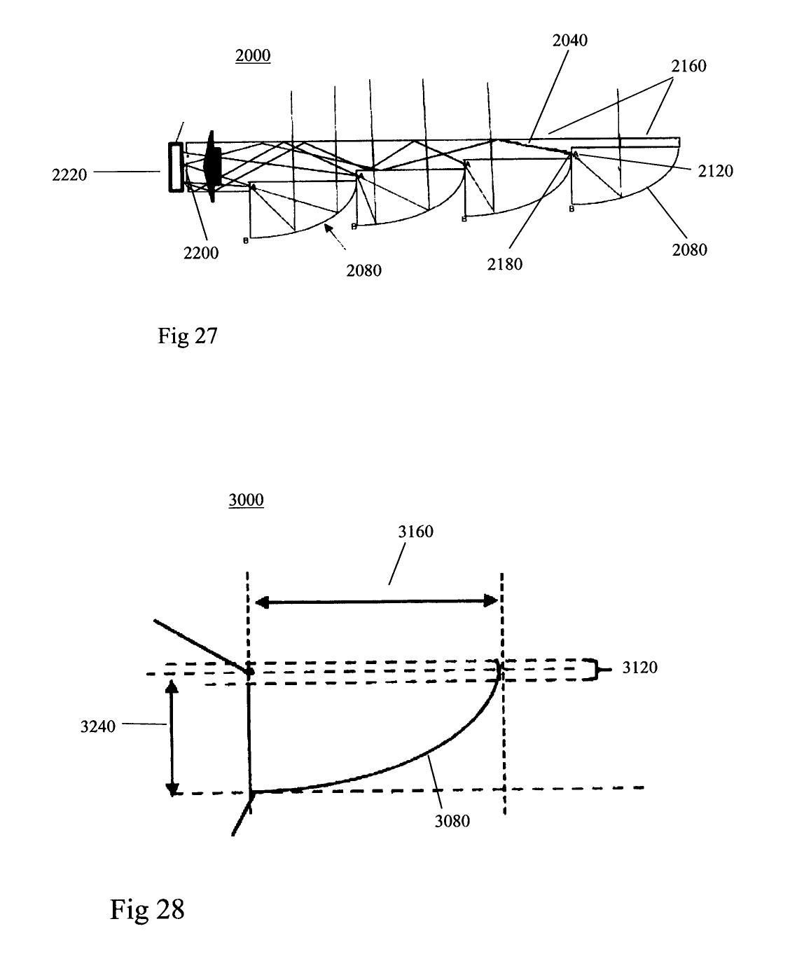

In a fifth embodiment a solarlight concentrator 2000 that includes an acrylic, PMMA or other transparent light guide 2040 configured with “stair step” features on one side where the step rise becomes the input rise facet 2120 for collecting light from a concentrating reflector 2080 positioned to direct light from a ray direction principally parallel to the face of the rise facet 2120 and principally parallel to the sun rays in to the guide 2040 is shown in FIG. 27.

The first surface, or top view in FIG. 27 is parallel to all the “run facets 2160.” Therefore with each additional step added to add additional parabolic sections 2080, the thickness of the light guide 2040 is increased by the thickness of the step rise height (See FIG. 28). The thickness of the light wave-guide 2040 over the first parabolic section 2080 at the thin end of the wave-guide 2040 only needs to be thick enough for structural support of that section since it does not conduct light toward the output. Light passing through the wave-guide 2040 from the top, or sun side, to the parabolic section 2080 passes through unobstructed like a window pane. The only losses here are due to Fresnel reflections from the upper and lower surfaces of wave-guide 2040 and absorption within the guide 2040. Fresnel losses can be minimized with anti-reflection thin film coatings or “moth eye” type structures such as those produced by Fresnel Optics, Inc.

The incoming solar radiation then passes through the air cavity and is reflected from the specular parabolic reflector section 2080 to pass through the focus A 2180 and enter the light guide 2040 through the rise facet 2120. This transition from air to the acrylic light guide 2040 refracts the light rays according to Snell's Law to the extent that all rays entering are within the TIR (total internal reflection) angle of greater than about 41 degrees relative to the normal to the light wave-guide 2040 upper and lower surfaces and thereby except for absorption and scattering of the light guide material, propagate in TIR losslessly (e.g., without loss) down the light wave-guide 2040 to the exit end 2200 where it illuminates PVC 2220.

In the exemplary section 3000 shown in FIG. 28, the curve 3080 is a parabolic section conforming to the function:

Y=2X/(4a)

where X and Y are measured from the Vertex as shown and a=distance from the vertex to the focus as shown as reference character 3240 in FIG. 28.

The parabolic section is truncated when the Y value equals the focus height plus ½ of the rise height 3120. The rise height 3120 is chosen to minimize thickness of the wave-guide 2040 while being large enough to etendue match (i.e., capture) the solid angular extent of the sun (approximately 0.5 degrees full angle) integrated over the run length (3160 in FIG. 28) to the 90 degree exit angular extent of the rays passing through the focus of the parabolic section 2080 and entering the wave-guide 2040 plus some additional height to allow for reflection surface tolerances and sun tracking tolerance which both have the effect of tilting the incoming sun rays off normal axis.

It should be noted that many other aspheric and nonaspheric curve functions for the mirror surface which that serve to direct the incoming sun's rays to the entrance aperture of the rise 2120 around the focus are also functional and may offer additional advantages and improvements in efficiency. For instance, the focal point could be shifted vertically as the parabolic curve is generated to more evenly distribute the power over the rise facet 2120 to prevent localized heating. Additionally the rise facet 2120 could be a series of linear sections of varying angle to better accommodate the varying input angles from the parabolic sections 2080.

An important reason for using an air interface to the rise facet 2120 for the incoming rays is that additional refraction occurs to the ray direction inside the wave-guide 2040 as it enters bending the ray toward the longitudinal axis of the wave-guide 2040 and more into the TIR range. In one embodiment of the invention all rays over the 0 to 90 degree range from the parabolic surface of the parabolic sections 2080 will enter the guide 2040 within TIR.

In one embodiment the parabolic segment and the vertical section of the parabolic sections 2080 from the vertex to the focus can be also made from an acrylic wall and molded as part of the light guide 2040. Since the cross sections can be constant, the product can be manufactured by Acrylic plastic extrusion in the direction out of the page. The part can be reflectorized (made into a reflector) on the bottom by evaporating aluminum, silver, or other specular material or by thin film interference coatings on the outer surface or the inner surface of the parabolic section completing the product. Methods and materials for carrying out acrylic extrusion, injection molding and casting may be found at

http://www.plexiglas.com/acrylicresin/technicaldata/extrusion;
http://www.plexiglas.com/acrylicresin/technicaldata/injectionmolding; and
http://www.acryliccasting.com/id14.html, respectively, each of which is incorporated herein by reference in its entirety.

Additionally and instead of metal specular coating to reflectorize the parabolic sections 2080, thin film interference filters may be applied by JDS Uniphase, Inc.'s custom optics division that can effectively reflect only light wavelengths into the guide 2040 that are appropriate for the particular photovoltaic devices being used. Thin films and thin film techniques include those described in “Thin Film Custom Optics” available at http://www.jdsu.com/product-literature/thinfilmco_br_co_ae.pdf (incorporated herein by reference in its entirety) and “JDSU Interference Filter Handbook, Second Edition” (incorporated herein by reference in its entirety). Other conventional reflectorizing techniques such as those described in “Thin Films for Optical Systems”, François R. Flory, published by CRC Press, 1995, ISBN 0824796330, 9780824796334 (incorporated herein by reference in its entirety) may also be used. The film can be designed to pass unwanted wavelengths, such as infra-red and ultra-violet, through the back and out to reduce heating and long term damage to the PVC and wave-guide.

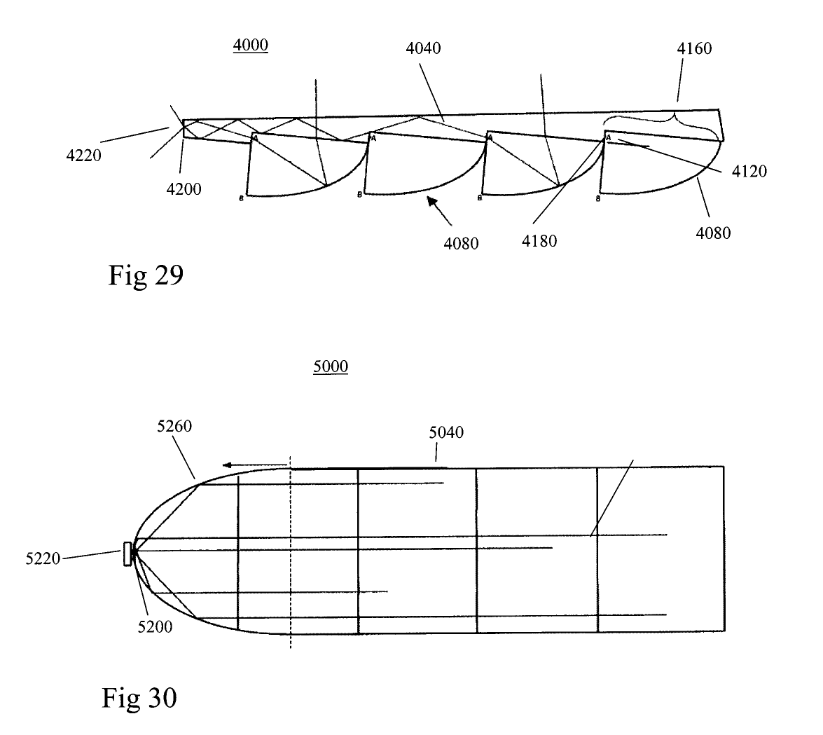

Another embodiment introduces a stair-stepped taper to the light guide 4000 as shown in FIG. 29. Such a light guide 4000 can include a wave-guide 4040, parabolic sections 4080 having a rise 4120 and a run 4160, and a PVC 4220 positioned at an exit end 4200 of the wave-guide 4040. This serves to make the system thinner and by varying the angle of taper, additional gain can be achieved thereby adding an additional optical gain element to the system. The taper can be allowed to vary by stage from one end to the other in order to minimize the TIR limitation of elements more distant from the output end of the light guide 4000 as additional concentration from the tapered sections increases the solid angle extent as the cross sectional area of the guide 4000 is reduced preserving the etendue of the system.

While this embodiment adds an additional stage of gain for the system and produces a thinner product, a gain limitation is imposed when the increasing TIR angle which results from the more steep taper causes the ray angle to exceed the TIR angle and light begins to escape from the guide 4000.

An additional gain stage can be added by tapering the width of the wave-guide 5000 as shown in the plan view of the extrusion in FIG. 30.

The untapered wave-guide section 5040 may be of one piece with tapered wave-guide section 5260. The particular taper in this region 5260 can be any of various optical concentration functions such as straight linear taper or Compound Parabolic Concentrator (CPC) functions to achieve the desired output uniformity and concentration level. In these cases the chosen function can be maximally efficient if the rays do not exceed the TIR limit of the light guide material as in the case above for the tapered guide 5000. More aggressive concentration is possible however by coating the side walls of the guide 5000 in the concentration region with a specular reflector such as the one used in the parabolic segments 2080 shown in FIG. 27. Light exits the tapered section at exit point 5200 where it illuminates SPC 5220. A description of exemplary coatings may be found at

http://www.kruschwitz.com/HR's.htm; http://www.goldstone-group.com/en/products_view.asp?pid=23; http://www.okjvc.com/products.asp?id=21 (incorporated herein by reference in its entirety).

Additionally, a reflectorized end cap (not shown) can be added to the open parabolic ends of the third stage region to further reduce collection losses and maximize efficiency. Additionally, a reflectorized end cap (not shown) can be added to each of the open parabolic section ends along the entire system to lower the sun tracking tolerance in the axis perpendicular to the concentration direction of the parabolic sections.

In a preferred embodiment, the concentrator is constructed using an Acrylic resin such as Plexiglas V825UVA5A manufactured by Altuglas International or other optically clear material which is injection moldable, injection-compression moldable, or extrusion moldable.

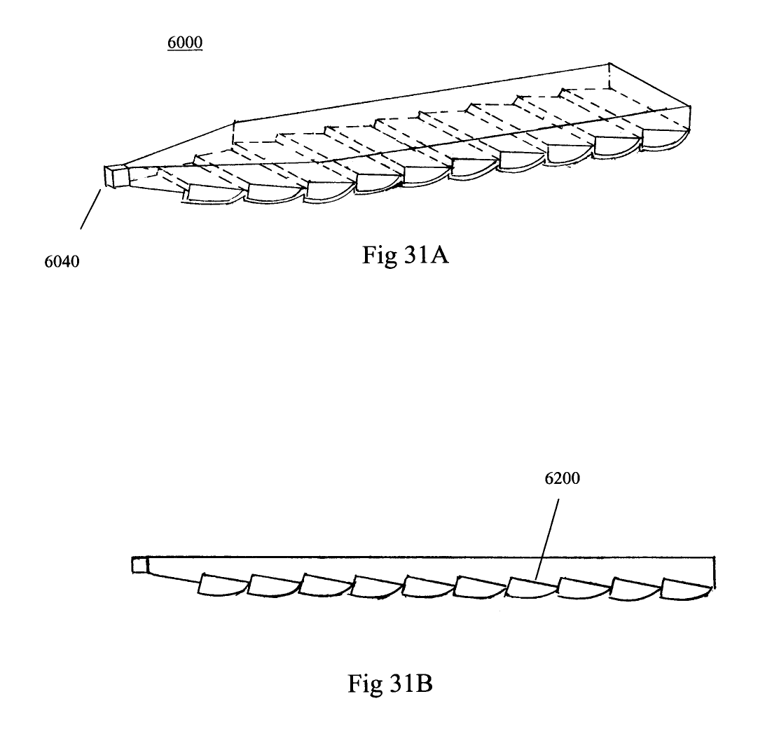

In the preferred embodiment the Acrylic material is formed using a linear extrusion molding process such as that described by Altuglas International's Plexiglas Acrylic Molding Resin Technical Data in Extrusion on their web site: www.plexiglas.com/acryolicresin/technicaldata/extrusion, or IAPD magazine, August/September 2003 (incorporated herein by reference in its entirety). The extrusion direction of the components 6200 is out of the page as viewed in FIG. 31B.

The extruded lengths are crosscut to width using a common plastic saw and the cut sides are polished or fly cut to an optical finish suitable for total internal reflection. The more fine the side polish, the more efficient the reflection would be and therefore selected to meet cost and performance tradeoffs of a particular application. Plastic fabrication that may be used to make the light concentrator of the invention may be found at http://website.lineone.net/mike.bissett/advice.htm (incorporated herein by reference in its entirety).

An isometric rendering of an extruded wave-guide 6000 is shown in FIG. 31A. Also shown at the left end is a photovoltaic cell assembly 6040 positioned to receive the concentrated sunlight for conversion to electricity. The photocell 6040 may be either attached or unattached and fixed in position relative to the concentrating light guide 6000 by external mechanical means.

In the limit the maximum concentration ratio of this system is simply the surface area of the plan view divided by the surface area of the output edge region, also known as the geometrical concentration ratio.

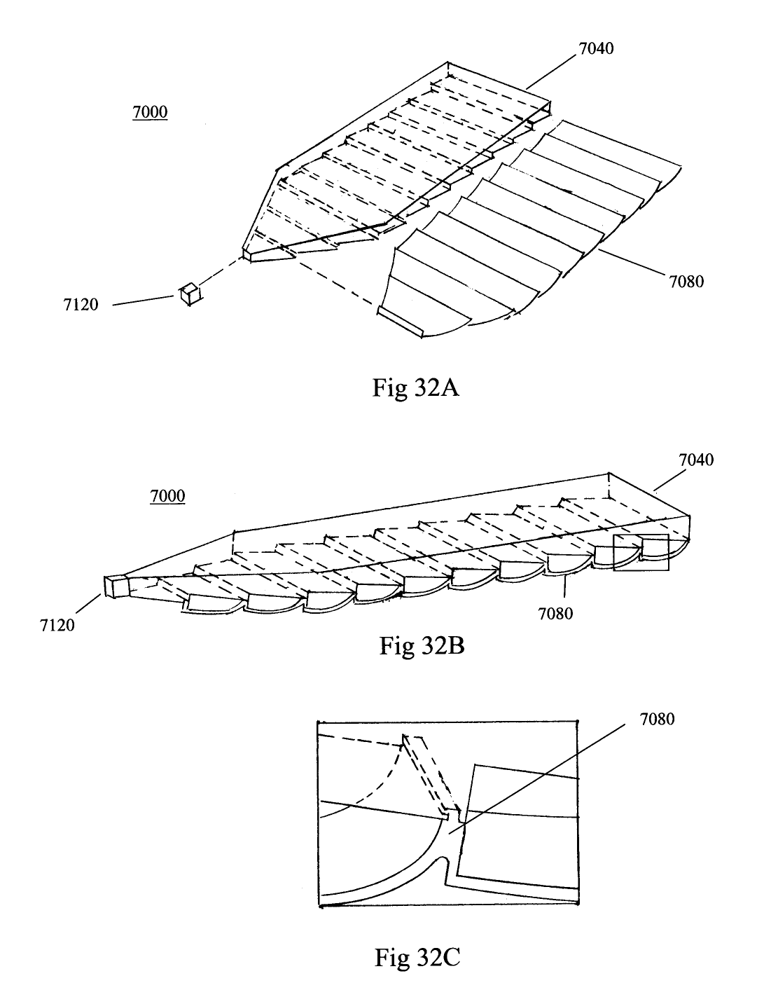

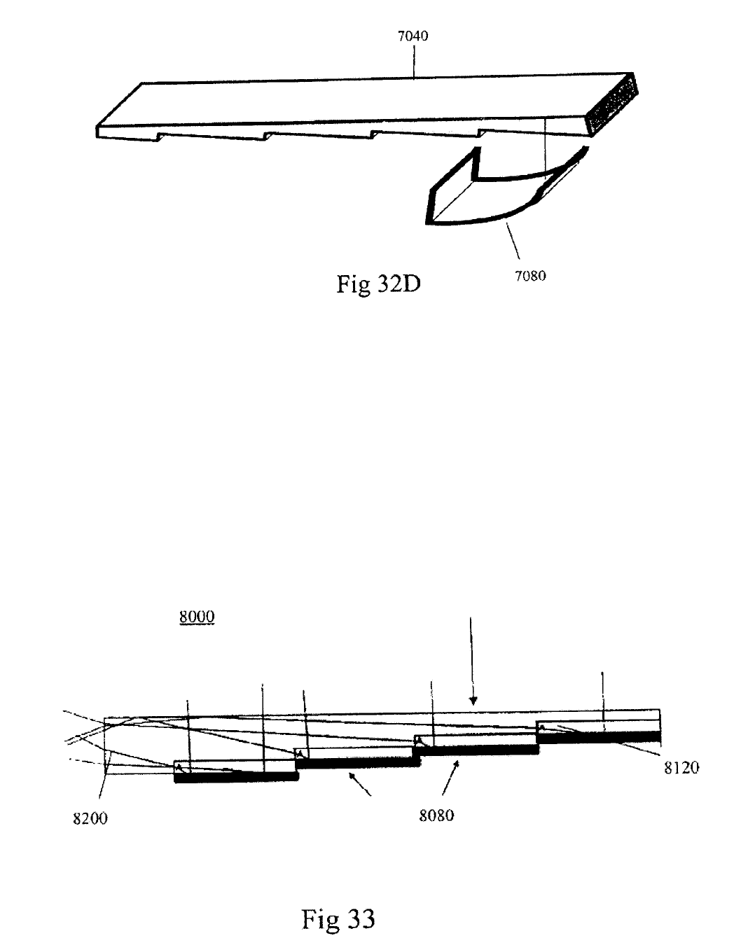

Another assembly method and construction is shown in FIGS. 32A, 32B and 32C. The concentrating light guide 7000 is produced as two pieces comprising a top 7040 and bottom 7080 sections with a PVC 7120 affixed in close proximity to an exit point. These sections are then seamed together as shown in FIG. 32C by glue, mechanical interlocks or alignment features and/or glued, or connected using any of various mechanical fastening means using mechanical features molded into each respective part.

In this embodiment, as all surfaces are exposed prior to assembly, secondary coatings, machine finishing, or polishing are possible if necessary to produce the surface finish of feature secondary machining required on any of the surface sections.

As shown in FIG. 32D, another advantage of this construction is that the upper wave-guide 7040 may be made of optical grade Acrylic, glass or other transparent high index material, while the lower parabolic reflector section or sections 7080 can be made of another material such as aluminum or other lower cost plastic since light does not have to propagate through the material. Aluminum fabrication methods and materials that may be used to make the light concentrator of the invention may be found at

http://www.bonlalum.com/Login/SlsMfg/extrusion_process.jsp (incorporated herein by reference in its entirety).

Another advantage of this construction is that material wall sections in cross section can be designed such that there is less variation in the extremes of wall thickness and thereby allow for more uniform extrusion processing which produces a more geometrically accurate part.

Another advantage of this construction is that, due to the open exposure of all surfaces, manufacturing means other than extrusion may be used such as injection molding, compression-injection molding, casting, die casting, or secondary machining of various material stocks are feasible.

Another advantage of this construction is that the specular reflection surfaces may be accessed for secondary operation coatings, polishing, or insertion and attachment of high efficiency specular reflection films such as 3M Vikuiti™ ESR (Enhanced Spectral Reflector) film on the parabolic surfaces as well as secondary sputtering or evaporation of materials such as silver or aluminum to make the specular surfaces.

In another embodiment of the system a HOE (holographic optical element) can be used to perform the function of the parabolic segment, but would be easier to manufacture and can make the system thinner yet. These holographic or diffractive elements can be generated from real parabolic elements using holographic recording techniques well known in the industry or computer generated holographic elements that are available in the industry from such suppliers as Zebra Imaging or Fusion Optix. A description of the holographic techniques that may be used is provided in http://www.fou.uib.no/fd/1996/h/404001/kap02.htm (incorporated herein by reference in its entirety).

In another embodiment, FIG. 33 shows a light guide 8000 including the HOEs (holographic optical elements) or DOEs (diffractive optical elements) 8080. The light guide 8000 also includes run facets 8120 and a PVC can be placed at the exit end 8200 of the light guide 8000. Alternatively, the HOEs or DOEs shown in FIG. 33 may be replaced by reflective Fresnel lenses performing a cylindrical concentration function as in the previous examples.

Additionally, HOEs can provide functionality similar to the thin film interference coatings described above and selectively pass or reflect certain wavelengths as appropriate to the PV devices and light guide materials.

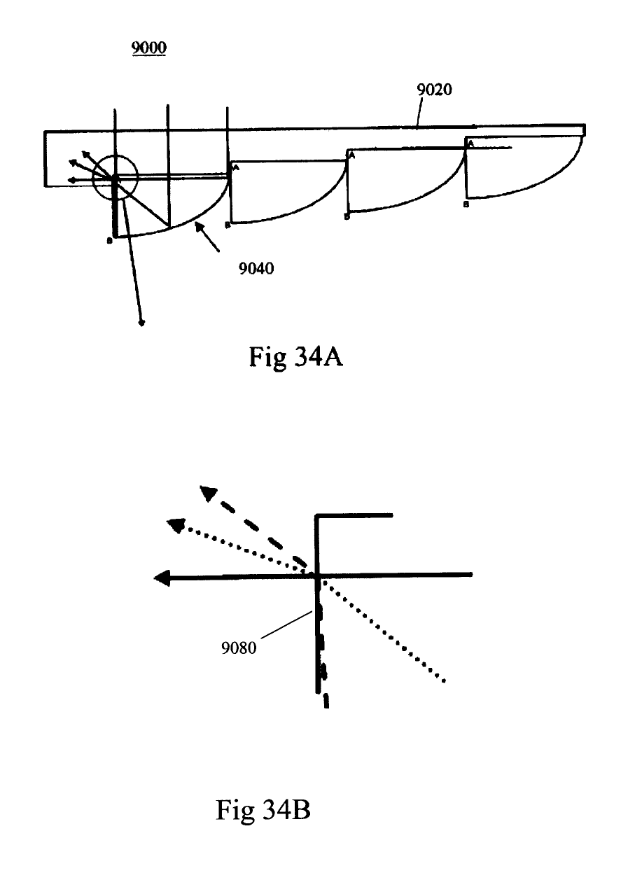

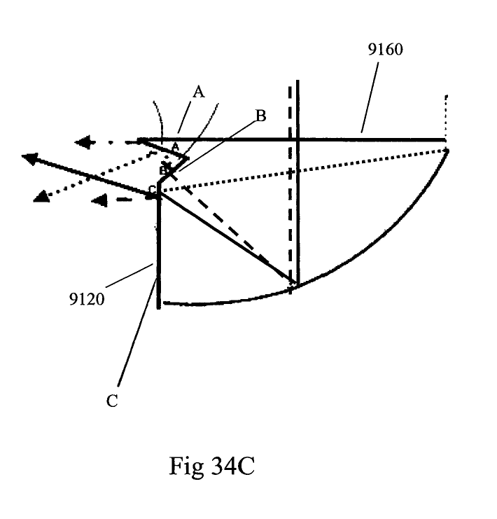

Another embodiment of a light guide 9000 using an alternative rise facet profile on wave-guide 9020 and compound segmented parabolic concentrating reflector 9040 is shown in FIGS. 34A, 34B, and 34C.

In other embodiments, the light after being refracted into the rise facet 9080 (e.g., a face) has an included ray extent of from 0 degrees to +42.16 degrees as a result of the 0 degrees to 90 degrees ray extent in air of the incident light from the parabolic reflector 9040 as shown in FIGS. 34A and 34B.

There are two efficiency loss effects with this configuration, which can be improved by the embodiment to follow, but can be traded off against the cost of implementation versus the performance needs of the application.

First, as the rays entering the rise facet 9080 become progressively parallel to the facet surface, the Fresnel reflection losses become increasingly significant and get to 100% in the limit thereby limiting the efficiency of the system significantly depending on the light guide material and any facet coating used.

Second, since the ray extent after entering the facet 9080 ranges from 0 degrees, which is ideal for propagation down the light guide, to +42.16 degrees which is near the TIR critical angle and fine for the system unless an additional gain stage is applied as described prior by tapering the light guide as shown in FIG. 29. In this case, non-zero ray angles are progressively increased due to the additional concentration and after a few reflections exceed the critical angle and escape the light guide 9000 thereby reducing efficiency.

FIG. 34C shows an embodiment that addresses this feature of the concentrating element. The rise facet 9120 is reconfigured into three segments (e.g., third, second and first faces) A, B, and C as shown in FIG. 34C. The A segment is angled at 25.5 degrees from the run facet 9160 and serves as a TIR angled mirror to the light rays from facet B. Facet B is angled at 45 degrees as shown and accepts light from a lower parabolic section whose shape is configured so that its focus is at the center of facet B. Facet C is at 90 degrees as shown with respect to the run facet 9160 and accepts light from an upper parabolic section configured so that its focus is at the center of facet C.

This serves to redistribute the ray extent within the light guide 9000 to a more symmetrical distribution around the ideal 0 degree, or parallel to the run facet run direction with a lower angle max of −22.5 degrees and an upper angle max of <+28.33 degrees which allow for more efficient propagation of light down the guide 9000 and additional gain without exceeding the TIR critical angle of the material and significantly reduces Fresnel losses on the rise facet segments 9120.

This approach is not limited to the particular angles and segment configuration shown above, but is exemplary of other design points which trade cost and performance to the particular application. For instance, more than 3 rise facets and more than 3 parabolic sections can be utilized to further reduce losses. Additionally continuous surface functions rather than sections could be contrived to further reduce losses.

We claim:

1. A solar concentrator assembly, comprising:
a stepped wave-guide assembly including at least one surface, comprising a set of parallel but offset adjacent surfaces, and an opposing surface, wherein the wave-guide assembly propagates light in a total internal reflection mode between the at least one surface and the opposing surface, and wherein the wave-guide assembly includes transition surfaces between the adjacent parallel surfaces and the transition surfaces include edges perpendicular to a longitudinal axis of the wave-guide assembly;
a reflective mirror assembly comprising a plurality of mirrors, each of the plurality of mirrors including at least one curved surface and being aligned to reflect the light to one of the transition surfaces between two of the parallel adjacent surfaces, and a mirror cross section of each of the plurality of mirrors has a different shape; and
an optical target providing unit to convert solar energy from the light propagated in the wave-guide assembly to a different form of energy.

2. The solar concentrator assembly of claim 1, wherein at least one of the transition surfaces between the adjacent parallel surfaces on the wave-guide assembly is a surface angled at approximately 45° to the longitudinal axis.

3. The solar concentrator assembly of claim 2, wherein at least one of the angled transition surfaces between the adjacent parallel surfaces is coated so as to form a specular reflective surface.

4. The solar concentrator assembly of claim 2, further comprising:
a specular reflective surface mounted in close proximity to at least one of the angled transition surfaces with a separation from the angled surface of at least a few wavelengths of light.

5. The solar concentrator assembly of claim 1, wherein at least one minor of the minor assembly exhibits curvature on one axis.

6. The solar concentrator assembly of claim 5, wherein the curvature of the mirror is aspheric.

7. The solar concentrator assembly of claim 1, wherein at least one mirror of the mirror assembly exhibits curvature on two orthogonal axes.

8. The solar concentrator assembly of claim 7, wherein the curvature of at least one of the two orthogonal axes is aspheric.

9. The solar concentrator assembly of claim 7, wherein the curvature in one section of the mirror differs from the curvature in another section of the mirror.

10. The solar concentrator assembly of claim 1, wherein the optical target providing unit is a photovoltaic cell to convert the solar energy to electrical power.

11. A solar concentrator assembly, comprising:
a stepped wave-guide assembly including at least one surface, comprising a set of parallel but offset adjacent surfaces, and an opposing surface, wherein the wave-guide assembly propagates light in a total internal reflection mode between the at least one surface and the opposing surface, and wherein the wave-guide assembly includes transition surfaces between the adjacent parallel surfaces, the transition surfaces include edges perpendicular to a longitudinal axis of the wave-guide assembly, and the transition surfaces are finished to support total internal reflection of the propagated light;
a reflective mirror assembly comprising a plurality of mirrors, each of the plurality of mirrors including at least one curved surface and being aligned to reflect the light to one of the transition surfaces between two of the parallel adjacent surfaces;
a light concentrating unit affixed to an exit of the wave-guide assembly; and
an optical target providing unit to convert solar energy from the light propagated in the wave-guide assembly to a different form of energy, wherein the optical target providing unit is affixed to the light concentrating unit.

12. The solar concentrator assembly of claim 11, wherein at least one of the transition surfaces between the adjacent parallel surfaces on the wave-guide assembly is orthogonal to the adjacent parallel surfaces.

13. The solar concentrator assembly of claim 11, wherein the light concentrating unit is a simple parabolic concentrator.

14. The solar concentrator assembly of claim 11, wherein the reflective mirror assembly extends to overlap the light concentrating unit such that at least one of the plurality of mirrors is positioned directly beneath the light concentrating unit.

15. The solar concentrator assembly of claim 11, wherein a mirror cross section of each of the plurality of mirrors has a different shape.

16. The solar concentrator assembly of claim 11, wherein at least one of the transition surfaces between the adjacent parallel surfaces on the wave-guide assembly is a compound surface comprising a plurality of segments each positioned at a different angle with respect to the adjacent parallel surfaces in the longitudinal direction.

17. An assembly, comprising:
a plurality of solar concentrator assemblies mounted to a common mechanical structure, each of the plurality of solar concentrator assemblies comprising:
a stepped wave-guide assembly including at least one surface, comprising a set of parallel but offset adjacent surfaces, and an opposing surface, wherein the wave-guide assembly propagates light in a total internal reflection mode between the at least one surface and the opposing surface, and wherein the wave-guide includes transition surfaces between the adjacent parallel surfaces and the transition surfaces include edges perpendicular to a longitudinal axis of the wave-guide assembly, and
a reflective mirror assembly comprising a plurality of mirrors, each of the plurality of mirrors including at least one curved surface and being aligned to reflect the light to one of the transition surfaces between two of the parallel adjacent surfaces, and a mirror cross section of each of the plurality of minors has a different shape; and
a plurality of photovoltaic cells to convert solar energy from the light propagated in the wave-guide assembly to a different form of energy, each of the plurality of photovoltaic cells being positioned at an exit of a corresponding one of the plurality of solar concentrator assemblies, and the plurality of photovoltaic cells are electrically connected.
